(19) United States
(12) Patent Application Publication
(10) Pub. No.: US 2024/0371887 A1
(43) Pub. Date: Nov. 7, 2024

(54) THIN FILM TRANSISTOR, ARRAY SUBSTRATE AND DISPLAY APPARATUS

(71) Applicant: BOE TECHNOLOGY GROUP CO., LTD., Beijing (CN)

(72) Inventors: Yuhang LU, Beijing (CN); Fengjuan LIU, Beijing (CN); Hehe HU, Beijing (CN); Zhengliang LI, Beijing (CN); Ce NING, Beijing (CN); Guangcai YUAN, Beijing (CN); Dandan ZHOU, Beijing (CN); Cheng XU, Beijing (CN)

(73) Assignee: BOE TECHNOLOGY GROUP CO., LTD., Beijing (CN)

(21) Appl. No.: 18/773,582

(22) Filed: Jul. 16, 2024

Related U.S. Application Data
(63) Continuation of application No. PCT/CN2023/086000, filed on Apr. 3, 2023.

(51) Int. Cl. H01L 27/12; G02F 1/1333; G02F 1/1362; G02F 1/1368; H01L 25/075; H01L 29/66; H01L 29/786; H10K 59/121

(52) U.S. Cl. CPC H01L 27/1225; H01L 27/127; H01L 29/66969; H01L 29/78633; H01L 29/7869; G02F 1/133345; G02F 1/133357; G02F 1/136209; G02F 1/1368; H01L 25/0753; H10K 59/1213

(57) ABSTRACT

A thin film transistor includes a first active layer, a second active layer, a first electrode, a second electrode and a third electrode. The first active layer includes a first surface away from a substrate. The second active layer includes a second surface in contact with the first surface. The first electrode, the first active layer and the second active layer have an overlapping region. The second electrode, the first active layer and the second active layer have an overlapping region. The third electrode, the first active layer and the second active layer have an overlapping region, and the third electrode is opposite to the second electrode. The second surface is located within the first surface, and a distance between at least part of a border of the second surface and a border of the first surface is less than or equal to 0.5 μm.

### CROSS-REFERENCE TO RELATED APPLICATION

This application is a Bypass Continuation Application of International Patent Application No. PCT/CN2023/086000, filed on Apr. 3, 2023, which is incorporated herein by reference in its entirety.

### TECHNICAL FIELD

The present disclosure relates to the field of display technologies, and in particular, to a thin film transistor, an array substrate and a display apparatus.

### BACKGROUND

According to different active layer materials, thin film transistors (TFTs) may be divided into oxide thin film transistors and amorphous silicon thin film transistors. Oxide thin film transistors have advantages of high mobility and simple manufacturing process, and are widely used in liquid crystal display apparatuses and active matrix organic light-emitting diode display apparatuses.

Micro light-emitting diodes (Micro LEDs) or mini light-emitting diodes (Mini LEDs) have attracted more and more attention due to their advantages of high resolution, low power consumption, high brightness, high color saturation, fast response speed, small thickness, long service life, and easy splicing. Micro LEDs refer to LEDs whose LED chip size is less than 50 μm, and Mini LEDs refer to LEDs whose LED chip size is in a range of 50 μm to 200 μm.

### SUMMARY

In an aspect, a thin film transistor is provided. The thin film transistor includes a first active layer, a second active layer, a first electrode, a second electrode and a third electrode. The first active layer is disposed on a substrate and includes a first surface away from the substrate. The second active layer is disposed on a side of the first active layer away from the substrate, and includes a second surface in contact with the first surface. The first electrode, the first active layer and the second active layer have an overlapping region among orthographic projections of the first electrode, the first active layer and the second active layer on the substrate. The second electrode, the first active layer and the second active layer have an overlapping region among orthographic projections of the second electrode, the first active layer and the second active layer on the substrate. The third electrode, the first active layer and the second active layer have an overlapping region among orthographic projections of the third electrode, the first active layer and the second active layer on the substrate, and the third electrode is opposite to the second electrode. The second surface is located within the first surface, and a distance between at least part of a border of the second surface and a border of the first surface is less than or equal to 0.5 μm.

In some embodiments, an orthographic projection, on the substrate, of a surface of the first active layer close to the second active layer covers an orthographic projection, on the substrate, of a surface of the second active layer close to the first active layer.

In some embodiments, the second surface includes a first region, and an orthographic projection of the first region on the substrate completely overlaps with an orthographic projection of the first electrode on the substrate; a distance between a border of the first region and the border of the first surface is less than or equal to 0.5 μm.

In some embodiments, an included angle between a sidewall of the first active layer and the substrate is in a range of 10° to 90°; and/or, an included angle between a sidewall of the second active layer and the substrate is in a range of 10° to 90°.

In some embodiments, the first electrode is disposed on a side of the second active layer away from the substrate. A carrier mobility of the first active layer is less than that of the second active layer, and a conduction band of the first active layer is greater than that of the second active layer.

In some embodiments, a ratio of a thickness of the first active layer to a thickness of the second active layer is in a range of 2 to 5.

In some embodiments, the thickness of the second active layer is greater than or equal to 5 nm; and/or the thickness of the first active layer is greater than or equal to 20 nm; and/or a sum of the thickness of the first active layer and the thickness of the second active layer is in a range of 30 nm to 50 nm.

In some embodiments, the thin film transistor further includes a third active layer disposed on a side of the second active layer away from the substrate, the third active layer including a third surface in contact with the second active layer. The second active layer further includes a fourth surface in contact with the third surface, the third surface is located within the fourth surface, and a distance between a border of the third surface and a border of the fourth surface is less than or equal to 0.5 μm.

In some embodiments, an included angle between a sidewall of the third active layer and the substrate is in a range of 10° to 90°.

In some embodiments, a thickness of the third active layer is in a range of 5 nm to 10 nm; and/or a sum of a thickness of the first active layer, a thickness of the second active layer, and a thickness of the third active layer is in a range of 30 nm to 50 nm.

In some embodiments, a material of the first active layer includes indium gallium zinc oxide, praseodymium-doped indium zinc oxide, or aluminum-doped indium tin zinc oxide; and/or a material of the second active layer includes indium zinc oxide, indium gallium oxide, indium gallium tin oxide or indium tin zinc oxide; and/or a material of the third active layer includes indium gallium zinc oxide, praseodymium-doped indium zinc oxide, or aluminum-doped indium tin zinc oxide.

In some embodiments, the first electrode is disposed on a side of the first active layer close to the substrate. A carrier mobility of the first active layer is greater than that of the second active layer, and a conduction band of the first active layer is less than that of the second active layer.

In some embodiments, a ratio of a thickness of the second active layer to a thickness of the first active layer is in a range of 2 to 5.

In some embodiments, the thickness of the first active layer is greater than or equal to 5 nm; and/or the thickness of the second active layer is greater than or equal to 20 nm; and/or a sum of the thickness of the first active layer and the thickness of the second active layer is in a range of 50 nm to 100 nm.

In some embodiments, a material of the first active layer includes indium zinc oxide, indium gallium oxide, indium gallium tin oxide or indium tin zinc oxide; and/or a material of the second active layer includes indium gallium zinc oxide, praseodymium-doped indium zinc oxide, or aluminum-doped indium tin zinc oxide.

In another aspect, an array substrate is provided. The array substrate includes a substrate and a plurality of thin film transistors each as described in any of the above embodiments. The plurality of thin film transistors are disposed on a side of the substrate.

In some embodiments, the array substrate further includes a conductive layer disposed on a side of the plurality of thin film transistors away from the substrate and connected to the plurality of thin film transistors. The conductive layer includes pads, and a pad is configured to be connected to a light-emitting chip.

In some embodiments, the array substrate has an array region and a bonding region; the array substrate further includes a driving circuit, and the plurality of thin film transistors are located in the driving circuit. The driving circuit includes a source-drain conductive layer including pins located in the bonding region, the pins being configured to be connected to a circuit board. A reducibility of a material of the source-drain conductive layer is lower than that of a material of the conductive layer.

In some embodiments, the array substrate further includes an insulating protective layer located on a side of the conductive layer away from the substrate. The insulating protective layer is provided therein with avoidance holes located in the array region, and an orthographic projection of an avoidance hole on the substrate at least partially overlaps with an orthographic projection of the pad on the substrate; a portion of the pad exposed by the avoidance hole is configured to be connected to the light-emitting chip.

In some embodiments, at least one thin film transistor is a driving transistor. An orthographic projection of the conductive layer on the substrate covers an orthographic projection of a first active layer included in the driving transistor on the substrate.

In some embodiments, the array substrate further includes a light-shielding layer located between the thin film transistor and the substrate, and an orthographic projection of the light-shielding layer on the substrate covers that of the first active layer on the substrate.

In some embodiments, the array substrate further includes a planarization layer and a first passivation layer. The planarization layer is located between the plurality of thin film transistors in the driving circuit and the conductive layer. The first passivation layer is located between the planarization layer and the conductive layer and is in contact with the planarization layer and the conductive layer. An adhesion force between the first passivation layer and the conductive layer is greater than an adhesion force between the conductive layer and the planarization layer.

In some embodiments, the array substrate further includes a light-emitting chip disposed on a side of the plurality of thin film transistors away from the substrate and connected to the plurality of thin film transistors.

In yet another aspect, a method for manufacturing an array substrate is provided. The array substrate has an array region and a bonding region. The manufacturing method includes: forming a source-drain conductive layer on a substrate, the source-drain conductive layer including pins located in the bonding region, and the pins being configured to be connected to a circuit board; forming a conductive layer on a side of the source-drain conductive layer away from the substrate, the conductive layer including pads located in the array region, and a pad being configured to be connected to a light-emitting chip; forming an initial insulating protective layer on a side of the conductive layer away from the substrate, an orthographic projection of the initial insulating protective layer on the substrate covering that of the conductive layer on the substrate; performing an annealing treatment on the array substrate; and removing portions of the initial insulating protective layer to form a plurality of avoidance holes, so as to form an insulating protective layer, an orthographic projection of an avoidance hole on the substrate at least partially overlapping with that of a pad on the substrate.

In yet another aspect, a display apparatus is provided. The display apparatus includes the array substrate as described in any of the above embodiments and a liquid crystal display panel, the liquid crystal display panel being disposed on a light-exit side of the array substrate.

In yet another aspect, a display apparatus is provided. The display apparatus includes the array substrate as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a sectional view taken along the section line A-A in FIG. 1;

FIG. 3 is another sectional view taken along the section line A-A in FIG. 1;

FIG. 4 is a sectional structure diagram of an array substrate, in accordance with some embodiments;

FIG. 5 is a top view showing a structure of a thin film transistor, in accordance with some embodiments;

FIG. 6 is a top view showing a structure of another thin film transistor, in accordance with some embodiments;

FIG. 7 is a sectional structure diagram of a thin film transistor, in accordance with some embodiments;

FIG. 8 is a sectional structure diagram of another thin film transistor, in accordance with some embodiments;

FIG. 9 is a structural diagram of yet another thin film transistor, in accordance with some embodiments;

FIG. 10 is a structural diagram of yet another thin film transistor, in accordance with some embodiments;

FIG. 11 is a structural diagram of yet another thin film transistor, in accordance with some embodiments;

FIG. 12 is a structural diagram of yet another thin film transistor, in accordance with some embodiments;

FIG. 13 is a structural diagram of yet another thin film transistor, in accordance with some embodiments;

FIG. 14 is a structural diagram of yet another thin film transistor, in accordance with some embodiments;

FIG. 15 is a structural diagram of yet another thin film transistor, in accordance with some embodiments;

FIG. 16A is a top view showing a structure of an array substrate, in accordance with some embodiments;

FIG. 16B is a top view showing a structure of another array substrate, in accordance with some embodiments;

FIG. 16C is a top view showing a structure of yet another array substrate, in accordance with some embodiments;

FIG. 16D is a top view showing a structure of yet another array substrate, in accordance with some embodiments;

FIG. 17 is a process diagram of manufacturing a thin film transistor, in accordance with some embodiments;

FIG. 18 is a characteristic curve of a thin film transistor, in accordance with some embodiments; and

FIG. 19 is a process diagram of manufacturing an array substrate, in accordance with some embodiments.

### DETAILED DESCRIPTION

The technical solutions in embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the term “connected” and extensions thereof may be used. The term “connected” should be understood in a broad sense. For example, the term “connected” may represent a fixed connection, a detachable connection, or a one-piece connection, or may represent a direct connection, or may represent an indirect connection through an intermediate medium.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

The term “substantially” as used herein includes a stated value and an average value within an acceptable range of deviation of a particular value determined by a person of ordinary skill in the art, considering measurement in question and errors associated with measurement of a particular quantity (i.e., limitations of a measurement system).

It should be understood that, in a case that a layer or element is referred to be on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in apparatuses, and are not intended to limit the scope of the exemplary embodiments.

The directional words such as “on” and “under” described herein are described from the perspective shown in the drawings and should not be understood as limitations on the embodiments of the present application. In addition, it should be understood in the context that when an element is referred to as being connected “on” or “under” another element, it can not only be directly connected “on” or “under” the another element, but can also be indirectly connected “on” or “under” the another element through an intermediate element.

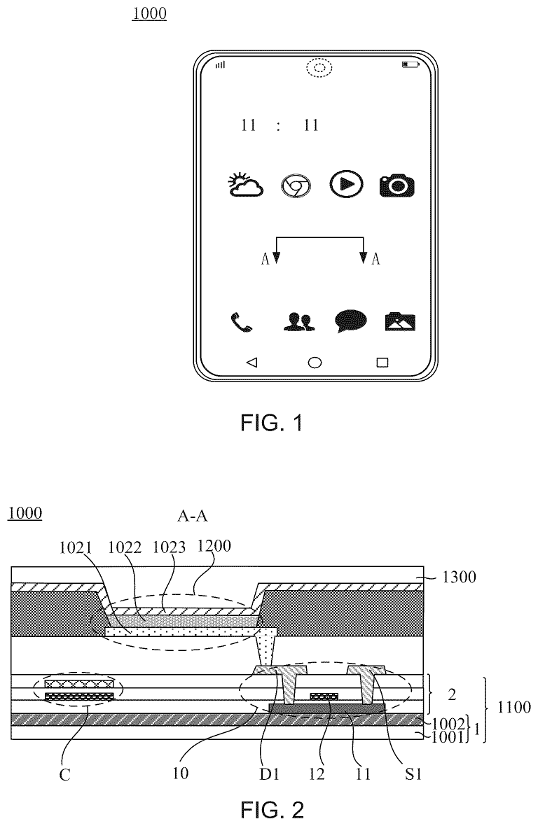

Embodiments of the present disclosure provide a display apparatus 1000, and as shown in FIG. 1, the display apparatus 1000 may be any product or component with a display function, such as a notebook computer, a tablet computer, a mobile phone, a personal digital assistant (PDA), a navigator, a wearable apparatus, an augmented reality (AR) apparatus, a virtual reality (VR) apparatus, or car central control screen.

In some embodiments, the display apparatus 1000 is an organic light-emitting diode (OLED) display apparatus. FIG. 2 is a sectional structure diagram of a display apparatus including an array substrate. As shown in FIG. 2, the display apparatus 1000 includes the array substrate 1100, light-emitting devices 1200 and an encapsulation layer 1300 that are stacked in sequence. The array substrate 1100 includes a substrate 1 and driving circuits 2.

As shown in FIG. 2, the substrate 1 can be a flexible substrate 1 or a rigid substrate 1. A material of the rigid substrate 1 may be glass, and a material of the flexible substrate 1 may be polyimide (PI). The substrate 1 may be of a single-layer structure or a multi-layer structure. For example, in the case where the substrate 1 is of the multi-layer structure, the substrate 1 includes a base 1001 and a buffer layer 1002 disposed on the base 1001. A material of the buffer layer 1002 may include silicon oxide, silicon nitride, or stacked silicon oxide and silicon nitride, which is not specifically limited in the embodiments of the present disclosure. A thickness of the buffer layer 1002 is in a range of 200 nm to 600 nm. For example, the thickness of the buffer layer 1002 is 200 nm, 400 nm or 600 nm, and the embodiments of the present disclosure are not limited thereto.

As shown in FIG. 2, the driving circuit 2 is disposed on a side of the substrate 1, and the driving circuit 2 includes a plurality of thin film transistors 10 and a storage capacitor C. The thin film transistor 10 is, for example, an oxide thin film transistor. The oxide thin film transistor has high carrier mobility and can improve the response speed of the thin film transistor 10. For example, the driving circuit 2 has a structure with a 2T1C, 5T2C, 6T1C, 6T2C, 7T1C, 7T2C or 9T2C, and the embodiments of the present disclosure are not limited thereto. For example, the driving circuit 2 has the 7T1C structure. The driving circuit 2 with xTyC means that the driving circuit 2 includes x thin film transistors T and y capacitors C.

The light-emitting device 1200 includes an anode 1021, a light-emitting functional layer 1022 and a cathode layer 1023. The anode 1021 is used for providing holes. The anode 1021 and the cathode layer 1023 respectively inject holes and electrons into the light-emitting function layer 1022, and light emission is generated when excitons generated by combination of the holes and the electrons transition from an excited state to a ground state.

The encapsulation layer 1300 is disposed on a side of the cathode layer 1023 away from the substrate 1. The encapsulation layer 1300 includes encapsulation film(s). The number of encapsulation films included in the encapsulation layer 1300 is not limited. In some embodiments, the encapsulation layer 1300 includes one encapsulation film, or two or more encapsulation films that are stacked. For example, the encapsulation layer 1300 includes three encapsulation films that are stacked in sequence.

In the case where the encapsulation layer 1300 includes three encapsulation films that are stacked in sequence, an encapsulation film located in the middle layer is made of an organic material, and encapsulation films located at both sides of the encapsulation layer 1300 are made of an inorganic material. The organic material is, for example, polymethyl methacrylate (PMMA) or PI.

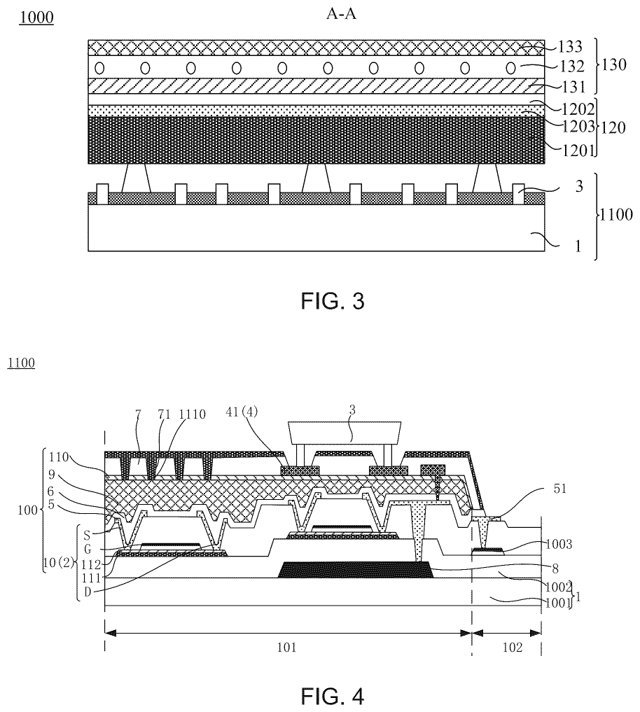

In some other embodiments, FIG. 3 is a sectional structure diagram of another display apparatus including an array substrate. The display apparatus 1000 may be a Micro LED display apparatus or a Mini LED display apparatus. As shown in FIG. 3, the display apparatus 1000 includes the array substrate 1100. As shown in FIG. 4, the array substrate 1100 includes a substrate 1, driving circuits 2 and light-emitting chips 3. The light-emitting chip 3 is disposed on a side of the driving circuit 2 away from the substrate 1. That is, the light-emitting chip 3 is disposed on a side of a plurality of thin film transistors 10 included in the driving circuit 2 away from the substrate 1. The light-emitting chip 3 is connected to the plurality of thin film transistors 10, so that the thin film transistors 10 can drive the light-emitting chip 3 to emit light. The array substrate 1100 can be directly used for image display, or can be used as a backlight source of the display apparatus 1000 for providing backlight for the display apparatus 1000. The light-emitting chip 3 may be a Micro LED chip or a Mini LED chip.

In the case where the array substrate 1100 is directly used for image display, the light-emitting chips 3 may include first light-emitting chips for emitting light of a first color, second light-emitting chips for emitting light of a second color, and third light-emitting chips for emitting light of a third color. For example, the first color, the second color and the third color are red, green and blue, respectively.

In the case where the array substrate 1100 is used as the backlight source of the display apparatus 1000 for providing backlight for the display apparatus 1000, the light-emitting chips 3 may include fourth light-emitting chips for emitting light of a fourth color, and the fourth color may be blue or white, which is not specifically limited in the embodiments of the present disclosure. In the following embodiments of the present disclosure, the display apparatus 1000 is described by taking an example where the array substrate 1100 is used as the backlight source of the display apparatus 1000 for providing backlight for the display apparatus 1000.

As shown in FIG. 3, the display apparatus 1000 further includes optical films 120 and a liquid crystal display panel 130. The optical films 120 are located on a light-exit side of the array substrate 1100, and the liquid crystal display panel 130 is located on a side of the optical films 120 away from the array substrate 1100. That is, the liquid crystal display panel 130 is located on the light-exit side of the array substrate 1100. The light-exit side of the array substrate 1100 refers to a side of the array substrate 1100 from which light exits.

As shown in FIG. 3, the liquid crystal display panel 130 includes an array plate 131, a liquid crystal layer 132 and a color filter substrate 133 that are stacked. The array plate 131 is closer to the array substrate 1100 than the color filter substrate 133.

The array plate 131 can include a plurality of pixel circuits and a plurality of pixel electrodes, and the plurality of pixel circuits are arranged in an array. The plurality of pixel circuits are electrically connected to the plurality of pixel electrodes in a one-to-one correspondence, and the pixel circuits are used to provide voltages to respective pixel electrodes.

The color filter substrate 133 can include a common electrode and a color filter. In the case where the array substrate 1100 emits the white light, the color filter can include red filter portions, green filter portions, and blue filter portions. The red filter portions can only allow the red light in the incident light to pass through, the green filter portions can only allow the green light in the incident light to pass through, and the blue filter portions can only allow the blue light in the incident light to pass through. In the case where the backlight provided by the array substrate 1100 is the blue light, the color filter can include red filter portions and green filter portions.

The liquid crystal layer 132 includes a plurality of liquid crystal molecules 133. An electric field may be formed between the pixel electrode and the common electrode, and liquid crystal molecules located between the pixel electrode and the common electrode may be deflected under the action of the electric field, thereby changing the amount of light passing through the liquid crystal layer 132, and achieving the preset brightness of the light emitted through the liquid crystal layer 132.

It can be understood that, the array substrate 1100 is used for providing backlight, and the light can pass through the array plate 131 and be incident onto the liquid crystal molecules of the liquid crystal layer 132. The liquid crystal molecules are deflected under the action of the electric field formed between the pixel electrode and the common electrode, thereby changing the amount of light passing through the liquid crystal layer 132, and achieving the preset brightness of the light emitted through the liquid crystal layer 132. The light passes through the filter portions of different colors in the color filter substrate 133 and then exits. The exit light has various colors, such as red, green, and blue. The various colors of light cooperate with each other, so that the display apparatus 1000 displays images.

The optical films 120 include a diffusion plate 1201 and a composite film 1202 that are stacked in a direction perpendicular to and away from the array substrate 1100.

The diffusion plate 1201 uniformizes the light emitted by the array substrate 1100 to improve the uniformity of the emitted light, thereby reducing the risk of light shadows. The diffusion plate 1201 is also used to support the composite film 1202.

The composite film 1202 includes a lower diffusion sheet, a prism sheet and an upper diffusion sheet that are stacked, and the upper diffusion sheet is further away from the diffusion plate 1201 than the lower diffusion sheet. The lower diffusion sheet uniformizes the light emitted by the array substrate 1100. The prism sheet is used to increase the brightness of the light emitted by the array substrate 1100. The upper diffusion sheet is used to reduce the risk of the array substrate 1100 being scratched by the liquid crystal display panel 130, and can also reduce the risk of the liquid crystal display panel 130 being scratched by the prism sheet.

In some embodiments, the optical films 120 further include a quantum dot film 1203 that is located between the diffusion plate 1201 and the composite film 1202. The quantum dot film 1203 is used to convert the light emitted by the array substrate 1100. For example, in the case where the light emitted by the array substrate 1100 is the blue light, the quantum dot film 1203 converts the blue light into the white light, thereby improving the purity of the white light. For another example, the quantum dot film 1203 converts the blue light into red light and green light. In this way, the color filter in the color filter substrate 133 may be omitted, and the thickness of the display apparatus 1000 may be reduced, which is beneficial to achieving the light weight and small thickness of the display apparatus 1000.

In general, the brightness of the light emitted by the array substrate 1100 after passing through the optical films 120 is enhanced, and the purity of the emitted light is higher and the uniformity is better.

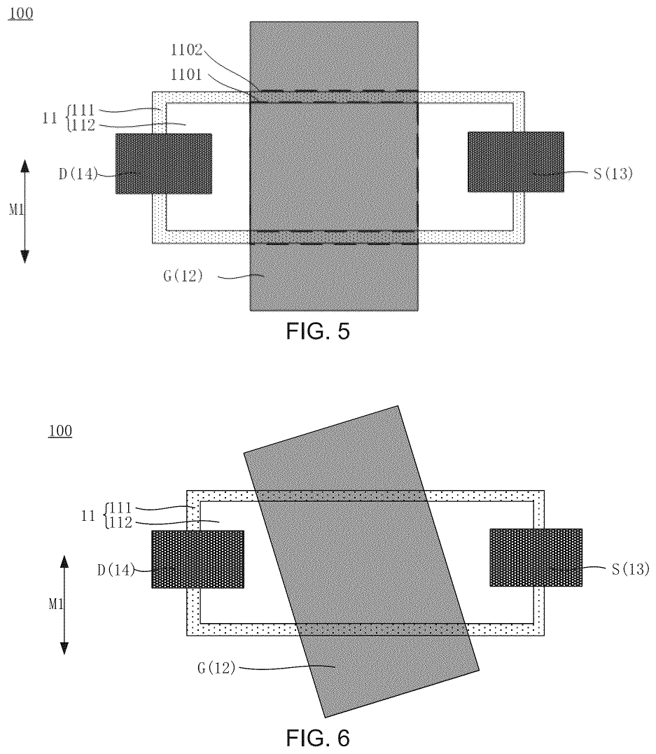

In some embodiments, as shown in FIGS. 5 to 8, the thin film transistor 10 includes an active layer pattern 11, a first electrode 12, a second electrode 13, and a third electrode 14.

The active layer pattern 11 is located on a side of the substrate 1. The active layer pattern 11 includes a first active layer 111 and a second active layer 112. That is, the thin film transistor 10 includes the first active layer 111 and the second active layer 112. The first active layer 111 is disposed on the side of the substrate 1, and the second active layer 112 is disposed on a side of the first active layer 111 away from the substrate 1. The mobility of portions of the first active layer 111 and the second active layer 112 close to the gate G is relatively high, which can make the carrier mobility of the thin film transistor 10 high. The negative bias temperature illumination stress (NBTIS) stability of portions of the first active layer 111 and the second active layer 112 far away from the gate G is relatively good, which can improve the stability of the bias temperature illumination threshold voltage drift of the thin film transistor 10, and reduce the risk of the threshold voltage of the thin film transistor 10 being negatively biased.

The first electrode 12, the first active layer 111 and the second active layer 112 have an overlapping region among their orthographic projections on the substrate 1. That is, an orthographic projection of the first electrode 12 on the substrate 1 and an orthographic projection of the first active layer 111 on the substrate 1 have a first overlapping region, the orthographic projection of the first electrode 12 on the substrate 1 and an orthographic projection of the second active layer 112 on the substrate 1 have a second overlapping region, and the first overlapping region and the second overlapping region have an overlapping portion.

The second electrode 13, the first active layer 111 and the second active layer 112 have an overlapping region among their orthographic projections on the substrate 1. That is, an orthographic projection of the second electrode 13 on the substrate 1 and the orthographic projection of the first active layer 111 on the substrate 1 have a third overlapping region, the orthographic projection of the second electrode 13 on the substrate 1 and the orthographic projection of the second active layer 112 on the substrate 1 have a fourth overlapping region, and the third overlapping region and the fourth overlapping region have an overlapping portion. The second electrode 13 is connected to the first active layer 111 and the second active layer 112.

The third electrode 14, the first active layer 111 and the second active layer 112 have an overlapping region among their orthographic projections on the substrate 1. That is, an orthographic projection of the third electrode 14 on the substrate 1 and the orthographic projection of the first active layer 111 on the substrate 1 have a fifth overlapping region, the orthographic projection of the third electrode 14 on the substrate 1 and the orthographic projection of the second active layer 112 on the substrate 1 have a sixth overlapping region, and the fifth overlapping region and the sixth overlapping region have an overlapping portion. The third electrode 14 is opposite to the second electrode 13. The third electrode 14 is connected to the first active layer 111 and the second active layer 112.

In some embodiments, as shown in FIGS. 5 and 6, the first electrode 12 extends in a first direction M1, and in the first direction M1, both ends of the first electrode 12 protrude from both ends of the active layer pattern 11 (that is, the both ends of the first electrode 12 protrude from both ends of the first active layer 111 and both ends of the second active layer 112). An included angle between the first direction M1 and the connection line between the second electrode 13 and the third electrode 14 may be set according to an actual situation. For example, as shown in FIG. 5, the included angle between the first direction M1 and the connection line between the second electrode 13 and the third electrode 14 is a right angle.

Alternatively, for example, as shown in FIG. 6, the included angle between the first direction M1 and the connection line between the second electrode 13 and the third electrode 14 is not a right angle. In this way, in some high-resolution display apparatuses 1000, the wiring space may be saved due to non-right angle. For example, the high-resolution display apparatuses 1000 include augmented reality devices or virtual reality devices. The embodiments of the present disclosure are not limited thereto.

In some embodiments, the second electrode 13 is the source S, and the third electrode 14 is the drain D. Alternatively, the second electrode 13 is the drain D, and the third electrode 14 is the source S. The embodiments of the present disclosure are described by taking an example where the first electrode 12 is the gate G, the second electrode 13 is the source S, and the third electrode 14 is the drain D.

When a voltage is applied to the gate G, the voltage on the gate G will cause the carriers of the active layer pattern 11 to gather in the portion of the active layer pattern 11 close to the gate G, and the gathered carriers will form a conductive channel. The conductive channel enables the carriers of the active layer pattern 11 to flow from the source S to the drain D, so as to achieve turn-on of the thin film transistor 10.

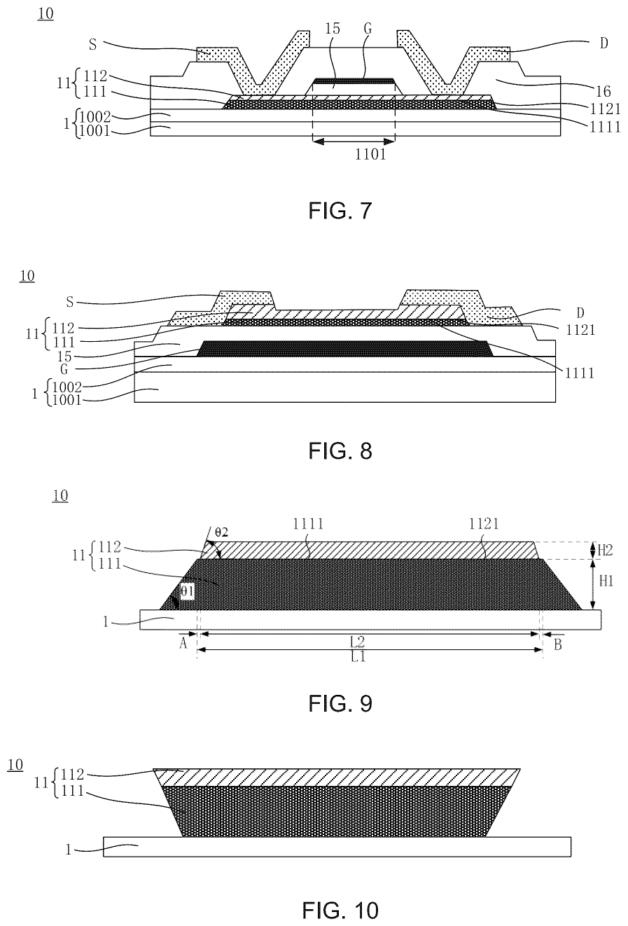

In some embodiments, as shown in FIGS. 7 and 8, in the process of forming the first active layer 111 and the second active layer 112, due to different materials of the first active layer 111 and the second active layer 112, the same etching solution has different etching rates for the first active layer 111 and the second active layer 112. If the etching rate of the first active layer is greater than that of the second active layer, the first active layer will be indented relative to the second active layer. That is, the edge of the active layer pattern will have an undercut structure. A large amount of oxygen atoms is lost at the undercut structure of the active layer pattern, resulting in a high oxygen vacancy concentration in the active layer pattern. Moreover, due to the obstruction of the undercut structure, the oxygen atoms lost in the active layer pattern are difficult to be replenished, resulting in numerous oxygen vacancy defects in the active layer pattern. The oxygen vacancy defects are donor defects and can provide carriers, resulting in too many carriers in the active layer pattern, and causing the threshold voltage of the thin film transistor to be negatively biased, i.e., causing a hump in the characteristic curve of the thin film transistor.

Based on the above structure, due to the undercut structure, when a first voltage is applied to the gate G, the carriers of the active layer pattern 11 gather in the portion of the first active layer 111 close to the gate G to form the conductive channel, and the thin film transistor 10 is turned on; and when a second voltage is applied to the gate G, the carriers of the active layer pattern 11 gather in the portion of the second active layer 112 close to the gate G to form the conductive channel, and the thin film transistor 10 is turned on. A value of the first voltage is not equal to a value of the second voltage. In this way, a “double channel” structure is formed. The “double channel” structure causes the thin film transistor 10 to have two turn-on voltages. As a result, the threshold voltage of the thin film transistor 10 is negatively biased, and the characteristic curve of the thin film transistor 10 has the hump.

FIG. 9 is a structural diagram showing that a second surface 1121 of the second active layer 112 is located within a first surface 1111 of the first active layer 111. As shown in FIG. 9, in order to solve the above problems, in a thin film transistor 10 provided in the embodiments of the present disclosure, the first active layer 111 includes the first surface 1111 away from the substrate 1, and the second active layer 112 includes the second surface 1121 in contact with the first surface 1111. The second surface 1121 is located within a range of the first surface 1111. In this way, the risk of the undercut at the edge of the active layer pattern 11 may be reduced, the risk of the threshold voltage of the thin film transistor 10 being negatively biased may be reduced (that is, the risk of the hump in the characteristic curve of the thin film transistor 10 may be reduced), and the power consumption of the thin film transistor 10 may be reduced.

In some embodiments, a distance between at least part of a border of the first surface 1111 and a border of the second surface 1121 is less than or equal to 0.5 μm. In this way, the gap between the border of the first surface 1111 and the border of the second surface 1121 is very small, which enables the first active layer 111 and the second active layer 112 to control the turn-on and turn-off of the thin film transistor 10 as a whole. That is, as the voltage of the gate G of the thin film transistor 10 changes, the thin film transistor 10 has only one turn-on voltage (the turn-on voltage refers to a voltage at which the thin film transistor 10 starts to turn on). Thus, the risk of the first active layer 111 and the second active layer 112 forming the “double channel” structure may be reduced, thereby reducing the risk of the threshold voltage of the thin film transistor 10 being negatively biased and reducing the risk of the hump in the characteristic curve of the thin film transistor 10.

For example, as shown in FIG. 9, a difference between a width L1 of the first surface 1111 and a width L2 of the second surface 1121 is less than or equal to 0.5 μm. That is, the sum of a distance A between left borders and a distance B between right borders is less than or equal to 0.5 μm.

In some embodiments, as shown in FIGS. 5 and 6, an orthographic projection, on the substrate 1, of the surface (i.e., the first surface 1111) of the first active layer 111 close to the second active layer 112 covers an orthographic projection, on the substrate 1, of the surface (i.e., the second surface 1121) of the second active layer 112 close to the first active layer 111. In this way, the surface of the second active layer 112 close to the first active layer 111 is located within the range of the first surface 1111.

In some embodiments, as shown in FIGS. 5 and 7, the second surface 1121 includes a first region 1101, and an orthographic projection of the first region 1101 on the substrate 1 completely overlaps with an orthographic projection of the gate G on the substrate 1. A distance between a border of the first region 1101 and the border of the first surface 1111 is less than or equal to 0.5 μm.

The first surface 1111 includes a second region 1102. An orthographic projection of the second region 1102 on the substrate 1 completely overlaps with the orthographic projection of the gate G on the substrate 1. A distance between the border of the second region 1102 and the border of the first region 1101 is less than or equal to 0.5 μm.

In some embodiments, a ratio of the etching rate of the first active layer 111 to the etching rate of the second active layer 112 is in a range of 0.2 to 1. The etching of the first active layer 111 is relatively slow, and the etching of the second active layer 112 is relatively fast, so that the first active layer 111 will not be indented relative to the second active layer 112. Thus, the second surface 1121 can be located within the range of the first surface 1111, which may reduce the risk of the undercut at the edge of the active layer pattern 11, reduce the risk of the threshold voltage of the thin film transistor 10 being negatively biased and the risk of the hump in the characteristic curve of the thin film transistor 10, and in turn reduce the power consumption of the thin film transistor 10.

FIG. 10 is a structural diagram showing the undercut at the edge of the active layer pattern 11. As shown in FIG. 10, the etching rate of the material of the first active layer 111 is much greater than that of the material of the second active layer 112. That is, the ratio of the etching rate of the first active layer 111 to the etching rate of the second active layer 112 is greater than 1. This will cause the undercut at the edge of the active layer pattern 11, thereby causing the negative bias of the threshold voltage of the thin film transistor 10 and the hump in the characteristic curve of the thin film transistor 10.

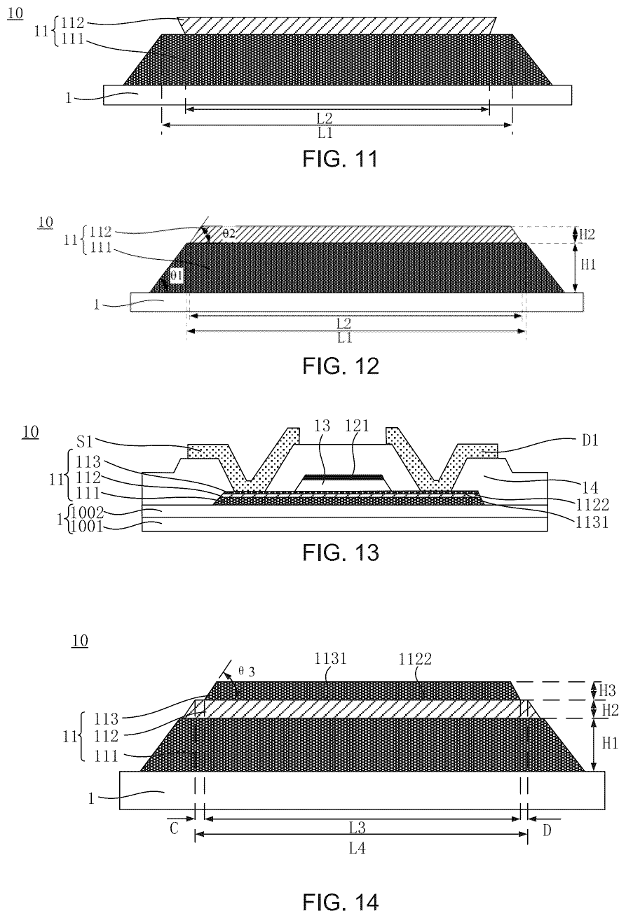

FIG. 11 is a structural diagram showing the undercut at the edge of the second active layer 112. As shown in FIG. 11, the etching rate of the material of the first active layer 111 is much lower than that of the material of the second active layer 112. That is, the ratio of the etching rate of the first active layer 111 to the etching rate of the second active layer 112 is less than 0.2. The portion of the second active layer 112 close to the substrate 1 is etched relatively fast, and the portion of the second active layer 112 far away from the substrate 1 is etched relatively slow, causing the undercut at the edge of the second active layer 112 and the negative bias of the threshold voltage of the thin film transistor 10 (i.e., the hump in the characteristic curve of the thin film transistor 10). In addition, the etching rate of the second active layer 112 is relatively fast, and the etching rate of the first active layer 111 is relatively slow, which causes the difference between the width L1 of the first surface 1111 and the width L2 of the second surface 1121 to be greater than 0.5 μm. That is, a step is generated between the first active layer 111 and the second active layer 112. As a result, the first active layer 111 and the second active layer 112 form the “double channel” structure, and the first active layer 111 and the second active layer 112 cannot control the turn-on and turn-off of the thin film transistor 10 as a whole.

In some embodiments, FIG. 12 is a structural diagram showing that the sidewall of the first active layer 111 forms an included angle θ1 with the substrate 1, and the sidewall of the second active layer 112 forms an included angle θ2 with the substrate 1. As shown in FIG. 12, the included angle θ1 between the sidewall of the first active layer 111 and the substrate 1 is approximately in a range of 10° to 90°. For example, the included angle θ1 between the sidewall of the first active layer 111 and the substrate 1 is 10°, 50° or 90°. The embodiments of the present disclosure are not limited thereto. In this way, the risk of the undercut at the edge of the first active layer 111 may be reduced, and the risk of the negative bias of the threshold voltage of the thin film transistor 10 may be reduced.

The included angle θ1 between the sidewall of the first active layer 111 and the substrate 1 is greater than or equal to 10°. For example, the included angle θ1 between the sidewall of the first active layer 111 and the substrate 1 is 15°.

The included angle θ1 between the sidewall of the first active layer 111 and the substrate 1 is less than 90°. For example, the included angle θ1 between the sidewall of the first active layer 111 and the substrate 1 is 85°. Thus, it may be possible to reduce the risk of the included angle θ1 between part of the sidewall of the first active layer 111 and the substrate 1 being greater than 90°, caused by the process error during the formation of the first active layer 111, thereby reducing the risk of the negative bias of the threshold voltage of the thin film transistor 10, caused by the undercut of part of the sidewall of the first active layer 111.

In some embodiments, as shown in FIG. 12, the included angle θ2 between the sidewall of the second active layer 112 and the substrate 1 is approximately in a range of 10° to 90°. For example, the included angle θ2 between the sidewall of the second active layer 112 and the substrate 1 is 10°, 50° or 90°. The embodiments of the present disclosure are not limited thereto. In this way, the risk of the undercut at the edge of the second active layer 112 may be reduced, and the risk of the negative bias of the threshold voltage of the thin film transistor 10 may be reduced.

The included angle θ2 between the sidewall of the second active layer 112 and the substrate 1 is greater than or equal to 10°. For example, the included angle θ2 between the sidewall of the second active layer 112 and the substrate 1 is 15°.

The included angle θ2 between the sidewall of the second active layer 112 and the substrate 1 is less than 90°. For example, the included angle θ2 between the sidewall of the second active layer 112 and the substrate 1 is 85°. Thus, it may be possible to reduce the risk of the included angle θ2 between part of the sidewall of the second active layer 112 and the substrate 1 being greater than 90°, caused by the process error during the formation of the second active layer 112, thereby reducing the risk of the negative bias of the threshold voltage of the thin film transistor 10, caused by the undercut of part of the sidewall of the second active layer 112.

In some embodiments, the included angle θ1 between the sidewall of the first active layer 111 and the substrate 1 is approximately in a range of 10° to 90°, and the included angle θ2 between the sidewall of the second active layer 112 and the substrate 1 is approximately in a range of 10° to 90°. In this way, the risk of the undercut at the edge of the active layer pattern 11 may be reduced, and the risk of the negative bias of the threshold voltage of the thin film transistor 10 may be reduced. For example, as shown in FIG. 9, the included angle θ1 between the sidewall of the first active layer 111 and the substrate 1 is not equal to the included angle θ2 between the sidewall of the second active layer 112 and the substrate 1. For another example, as shown in FIG. 12, the included angle θ1 between the sidewall of the first active layer 111 and the substrate 1 is equal to the included angle θ2 between the sidewall of the second active layer 112 and the substrate 1.

In some embodiments, as shown in FIG. 12, the included angle θ1 between the sidewall of the first active layer 111 and the substrate 1 is approximately in a range of 30° to 60°. For example, the included angle θ1 between the sidewall of the first active layer 111 and the substrate 1 is 30°, 45°, or 60°, and the embodiments of the present disclosure are not limited thereto. The included angle θ1 between the sidewall of the first active layer 111 and the substrate 1 is less than or equal to 60°. In this case, the sidewall of the first active layer 111 is relatively inclined, which may make the material deposited on the first active layer 111 better adhere to the sidewall of the first active layer 111.

In some embodiments, as shown in FIG. 12, the included angle θ2 between the sidewall of the second active layer 112 and the substrate 1 is approximately in a range of 30° to 60°. For example, the included angle θ2 between the sidewall of the second active layer 112 and the substrate 1 is 30°, 45°, or 60°, and the embodiments of the present disclosure are not limited thereto. The included angle θ2 between the sidewall of the second active layer 112 and the substrate 1 is less than or equal to 60°. In this case, the sidewall of the second active layer 112 is relatively inclined, which may make the material deposited on the second active layer 112 better adhere to the sidewall of the second active layer 112.

The included angle θ1 between the sidewall of the first active layer 111 and the substrate 1 is approximately in a range of 30° to 60°, and/or the included angle θ2 between the sidewall of the second active layer 112 and the substrate 1 is approximately in a range of 30° to 60°. In this way, the material deposited on the active layer pattern 11 may better adhere to the sidewall of the active layer pattern 11.

As shown in FIGS. 7 and 8, a material of the gate G may include silver, aluminum, chromium or copper, and the embodiments of the present disclosure are not limited thereto. For example, the material of the gate G includes copper. A thickness of the gate G is in a range of 50 nm to 150 nm. For example, the thickness of the gate G is 50 nm, 100 nm or 150 nm. The embodiments of the present disclosure are not limited thereto.

As shown in FIG. 7, the thin film transistor 10 further includes a gate insulating layer 15. A material of the gate insulating layer 15 may include silicon oxide (SiOx), silicon nitride (SiNx), silicon oxynitride (SiOxNy), aluminum oxide (Al2O3), or titanium oxide (TiOx), and the embodiments of the present disclosure are not limited thereto. For example, the material of the gate insulating layer 15 is silicon oxide. A thickness of the gate insulating layer 15 is in a range of 100 nm to 200 nm. For example, the thickness of the gate insulating layer 15 is 100 nm, 150 nm or 200 nm. The embodiments of the present disclosure are not limited thereto.

The gate G may be located on a side of the second active layer 112 away from the substrate 1 (as shown in FIG. 7). That is, the gate G is disposed above the active layer pattern 11, and in this case, the thin film transistor 10 is a top-gate thin film transistor 10. Alternatively, the gate G may be disposed on a side of the first active layer 111 close to the substrate 1 (as shown in FIG. 8). That is, the gate G is located below the active layer pattern 11, and in this case, the thin film transistor 10 is a bottom-gate thin film transistor 10.

As shown in FIG. 7, in the case where the thin film transistor 10 is the top-gate thin film transistor 10, the active layer pattern 11 is disposed on the substrate 1, the gate insulating layer 15 is located on a side of the active layer pattern 11 away from the substrate 1, and the gate insulating layer 15 is used for separating the gate G and the active layer pattern 11. The gate G is disposed on a side of the gate insulating layer 15 away from the substrate 1. The source S and the drain D are located on a side of the gate G away from the substrate 1.

As shown in FIG. 7, the thin film transistor 10 further includes an interlayer dielectric layer 16. The interlayer dielectric layer 16 is located on the side of the gate G away from the substrate 1. The interlayer dielectric layer 16 is used for separating the gate G from the source S and the drain D, and is also used for separating the source S and the drain D. The source S and the drain D are located on a side of the interlayer dielectric layer 16 away from the substrate 1, and the source S and the drain D are in contact with the active layer pattern 11 through via holes.

A material of the interlayer dielectric layer 16 may include an insulating material. For example, the material of the interlayer dielectric layer 16 includes silicon oxide, silicon nitride, silicon oxynitride, aluminum oxide or titanium oxide. The embodiments of the present disclosure are not limited thereto. For example, the material of the interlayer dielectric layer 16 is silicon oxide. A thickness of the interlayer dielectric layer 16 is in a range of 200 nm to 500 nm. For example, the thickness of the interlayer dielectric layer 16 is 200 nm, 350 nm or 500 nm. The embodiments of the present disclosure are not limited thereto.

As shown in FIG. 12, the included angle θ1 between the sidewall of the first active layer 111 and the substrate 1 is approximately in a range of 30° to 60°, and/or the included angle θ2 between the sidewall of the second active layer 112 and the substrate 1 is approximately in a range of 30° to 60°. In this way, the sidewalls of the first active layer 111 and the second active layer 112 are relatively inclined, which may make the interlayer dielectric layer 16 better adhere to the sidewalls of the first active layer 111 and the second active layer 112, and reduce the risk of the first active layer 111 and the second active layer 112 being short-circuited to the source S and the drain D, caused by breakage of the interlayer dielectric layer 16.

As shown in FIG. 8, in the case where the thin film transistor 10 is the bottom-gate thin film transistor 10, The gate G is disposed on the substrate 1, and the gate insulating layer 15 is disposed on the side of the gate G away from the substrate 1. The gate insulating layer 15 is used for separating the gate G and the active layer pattern 11. The active layer pattern 11 is disposed on the side of the gate insulating layer 15 away from the substrate 1. The source S and the drain D are directly in contact with the first active layer 111 and the second active layer 112.

The included angle θ1 between the sidewall of the first active layer 111 and the substrate 1 is approximately in a range of 30° to 60°, and/or the included angle θ2 between the sidewall of the second active layer 112 and the substrate 1 is approximately in a range of 30° to 60°. In this way, the sidewalls of the first active layer 111 and the second active layer 112 are relatively inclined, which may make the source S and the drain D better adhere to the sidewalls of the first active layer 111 and the second active layer 112, and reduce the risk of breakage of source S and drain D.

As shown in FIG. 7, in some embodiments, in the case where the gate G is disposed on the side of the second active layer 112 away from the substrate 1, the carrier mobility of the second active layer 112 is greater than that of the first active layer 111. The carriers in the active layer pattern 11 gather in the portion of the second active layer 112 close to the gate G, so as to form the conductive channel. The carriers may flow from the source S to the drain D to achieve the turn-on of the thin film transistor 10.

If the carrier mobility of the second active layer 112 is greater than or equal to the first threshold (e.g., the first threshold is 20 cm2/V·s), which may be considered that the carrier mobility of the second active layer 112 is relatively high. For example, the material of the second active layer 112 includes indium zinc oxide (IZO), indium gallium oxide (IGO), indium gallium tin oxide (IGTO), or indium tin zinc oxide (ITZO). The embodiments of the present disclosure are not limited thereto. For example, the material of the second active layer 112 includes IGTO.

In some embodiments, the NBTIS stability of the second active layer 112 is less than that of the first active layer 111. There are relatively few donor defects such as oxygen vacancy defects and hydrogen interstitial defects in the first active layer 111, which can reduce the concentration of the donor defects such as oxygen vacancy defects and hydrogen interstitial defects in the active layer pattern 11 (the donor defects may provide carriers). The carrier concentration of the second active layer 112 is not too high, which may reduce the risk of the threshold voltage of the thin film transistor 10 being negatively biased, and reduce the power consumption of the thin film transistor 10.

It should be noted that, the Ga—Ga bond in the oxide material has a relatively small bond length and a relatively large bond energy, and a large energy is required to break the Ga—Ga bond. That is, the stability of the Ga—Ga bond is relatively high. Thus, there are few donor defects such as oxygen vacancy defects and hydrogen interstitial defects in the oxide material, and there are not too many carriers in the oxide material, which reduces the risk of the negative bias of the threshold voltage of the oxide thin film transistor including the Ga material (that is, the NBTIS stability of the oxide material is relatively good).

The In—In bond has a relatively large bond length and a relatively small bond energy, and a small energy is required to break the In—In bond. That is, the stability of the In—In bond is poor. As a result, there are numerous donor defects such as oxygen vacancy defects and hydrogen interstitial defects in the oxide material, and there are numerous carriers in the oxide material, which leads to the negative bias of the threshold voltage of the oxide thin film transistor including the In material (that is, the NBTIS stability of the oxide material is relatively poor).

Based on the above reasons, in some embodiments, the material of the first active layer 111 includes indium atoms, and a content of the indium atoms is less than or equal to 40%. For example, the content of the indium atoms is 35%, 15% or 10%. The embodiments of the present disclosure are not limited thereto. The content of the indium atoms in the material of the first active layer 111 is relatively low, there are few donor defects such as oxygen vacancy defects and hydrogen interstitial defects in the first active layer 111, and the NBTIS stability of the first active layer 111 is relatively good.

In some embodiments, the material of the first active layer 111 includes crystalline oxide, high oxygen type oxide or doped oxide, and the embodiments of the present disclosure are not limited thereto.

For example, the material of the first active layer 111 includes the crystalline oxide. For example, the material of the first active layer 111 includes indium gallium zinc oxide (IGZO). In dry etching, plasma is difficult to affect the crystalline oxide. The material of the first active layer 111 includes IGZO, which may reduce the risk of the characteristic of the thin film transistor 10 being affected. In addition, the crystalline oxide can reduce scattering of carriers, so that the concentration of carriers in the first active layer 111 may be high, which may increase the mobility of carriers in the first active layer 111, and in turn increase the carrier mobility of the active layer pattern 11, increase the carrier mobility of the thin film transistor 10, increase the response speed of the thin film transistor 10 (e.g., a driving thin film transistor), and reduce the loss of the thin film transistor 10.

For another example, the material of the first active layer 111 includes the high oxygen type oxide. For example, the material of the first active layer 111 includes IGZO. For example, the mass ratio of the oxygen content in the high oxygen type oxide is approximately in a range of 50% to 80%. For example, the mass ratio of the oxygen content is 50%, 75% or 80%. The embodiments of the present disclosure are not limited thereto.

For yet another example, the material of the first active layer 111 includes the doped oxide, and the doping element in the doped oxide includes Al, Sn, Ga, or a rare earth element. The embodiments of the present disclosure are not limited thereto. For example, the material of the first active layer 111 includes aluminum-doped indium tin zinc oxide (Al-ITZO), praseodymium-doped indium zinc oxide (Pr-IZO) or Pr-IZYO. The embodiments of the present disclosure are not limited thereto.

The first active layer 111 is further away from the gate G than the second active layer 112. That is, the second active layer 112 is located between the first active layer 111 and the gate G. Light in a direction from a side, away from the second active layer 112, of the gate G to the second active layer 112 will be blocked by the gate G. The light cannot reach the second active layer 112, so that the energy band of the second active layer 112 is not bent, which reduce the risk of the carriers in the second active layer 112 drifting toward the gate insulating layer 15 and being captured by oxygen vacancies in the gate insulation layer 15, and in turn reduce the risk of the threshold voltage of the thin film transistor 10 being negatively biased, caused by carrier accumulation at the interface of the gate insulating layer 15.

Light directed to the second active layer 112 from the substrate 1 will be blocked by the first active layer 111. The light is incident on the first active layer 111, and there are few donor defects such as oxygen vacancy defects and hydrogen interstitial defects in the first active layer 111. Thus, the carrier concentration of the active layer pattern 11 is not too high, which may reduce the risk of the threshold voltage of the thin film transistor 10 being negatively biased.

In some embodiments, a conduction band of the first active layer 111 is greater than that of the second active layer 112. In this way, an electron potential barrier is formed between the second active layer 112 and the first active layer 111, which may reduce the risk of carriers in the second active layer 112 diffusing to the first active layer 111, and make most of the carriers located in the second active layer 112. Thus, the mobility of carriers in the second active layer 112 may be increased, and in turn the carrier mobility of the active layer pattern 11 may be increased, the carrier mobility of the thin film transistor 10 may be increased, the response speed of the thin film transistor 10 may be increased, and the loss of the thin film transistor 10 may be reduced.

In some embodiments, as shown in FIGS. 9 and 12, a ratio of the thickness H1 of the first active layer 111 to the thickness H2 of the second active layer 112 is in a range of 2 to 5. For example, the ratio of the thickness H1 of the first active layer 111 to the thickness H2 of the second active layer 112 is 2, 3.5 or 5. The embodiments of the present disclosure are not limited thereto.

The ratio of the thickness H1 of the first active layer 111 to the thickness H2 of the second active layer 112 is greater than or equal to 2. In this way, the second active layer 112 is relatively thin, which will not cause the concentration of carriers in the active layer pattern 11 to be too high, will not cause the threshold voltage of the thin film transistor 10 to be negatively biased, will not cause a large leakage current of the thin film transistor 10, and will not cause abnormal display of the display apparatus 1000.

The ratio of the thickness H1 of the first active layer 111 to the thickness H2 of the second active layer 112 is less than or equal to 5. In this way, the first active layer 111 is not too thick, which may reduce the risk of the threshold voltage of the thin film transistor 10 being biased, caused by an excessive thickness of the active layer pattern 11, and in turn reduce the risk of poor display of the display apparatus 1000.

In some embodiments, as shown in FIG. 9, the thickness H1 of the first active layer 111 is greater than or equal to 20 nm. The first active layer 111 is relatively thick, which will not cause the concentration of carriers in the active layer pattern 11 to be too high, will not cause the threshold voltage of the thin film transistor 10 to be negatively biased, and will not cause a large leakage current of the thin film transistor 10.

In some embodiments, as shown in FIG. 9, the thickness H2 of the second active layer 111 is greater than or equal to 5 nm. In this way, the second active layer 112 is not too thin, which will not cause the concentration of carriers in the second active layer 112 to be low, and will not cause a low carrier mobility of the second active layer 112. Moreover, during the process of manufacturing the second active layer 112, the thicknesses of portions of the second active layer 112 are uniform, so that the carrier mobility of each portion of the second active layer 112 is the same. Thus, the uniformity of the carrier mobility of the second active layer 112 may be improved. In addition, it may also be possible to reduce the risk of low carrier mobility of the second active layer 112 caused by a thin portion of the second active layer 112 being unable to pass carriers.

In some embodiments, as shown in FIG. 9, a sum of the thickness H1 of the first active layer 111 and the thickness H2 of the second active layer 112 is in a range of 30 nm to 50 nm. For example, the sum of the thickness H1 of the first active layer 111 and the thickness H2 of the second active layer 112 is 30 nm, 40 nm or 50 nm. The embodiments of the present disclosure are not limited thereto. The sum of the thickness H1 of the first active layer 111 and the thickness H2 of the second active layer 112 is greater than or equal to 30 nm. During the process of manufacturing the active layer pattern 11, the thicknesses of portions of the active layer pattern 11 are uniform, which may make the carrier mobility of each portion of the active layer pattern 11 the same, and may improve the uniformity of the carrier mobility of the active layer pattern 11. The sum of the thickness H1 of the first active layer 111 and the thickness H2 of the second active layer 112 is less than or equal to 50 nm, which may reduce the risk of the threshold voltage of the thin film transistor 10 being negatively biased, caused by an excessive thickness of the second active layer 112 (the excessive thickness of the second active layer 112 will cause an excessive carrier concentration of the active layer pattern 11). Or, the sum of the thickness H1 of the first active layer 111 and the thickness H2 of the second active layer 112 is less than or equal to 50 nm, which may reduce the risk of the threshold voltage of the thin film transistor 10 being biased, caused by an excessive thickness of the first active layer 111 (the excessive thickness of the first active layer 111 will cause the thickness of the active layer pattern 11 to be relatively large), and in turn reduce the risk of poor display of the display apparatus 1000.

In some embodiments, FIG. 13 is a structural diagram of the active layer pattern 11 including the first active layer 111, the second active layer 112 and a third active layer 113. FIG. 14 is a structural diagram showing that a third surface 1131 of the third active layer 113 is located within the second surface of the second active layer 112. As shown in FIGS. 13 and 14, the active layer pattern 11 further includes the third active layer 113. That is, the thin film transistor 10 further includes the third active layer 113. The third active layer 113 is disposed on the side of the second active layer 112 away from the substrate 1. The third active layer 113 includes the third surface 1131 in contact with the second active layer 112. The second active layer 112 further includes a fourth surface 1122 in contact with the third surface 1131. The third surface 1131 is located within the range of the fourth surface 1122. In this way, the risk of the undercut at the edge of the active layer pattern 11 is reduced, thereby reducing the risk of the threshold voltage of the thin film transistor 10 being negatively biased, and reducing the power consumption of the thin film transistor 10.

A distance between a border of the fourth surface 1122 and a border of the third surface 1131 is less than or equal to 0.5 μm, which enables the second active layer 112 and the third active layer 113 to control the turn-on and turn-off of the thin film transistor 10 as a whole. That is, as the voltage of the gate G of the thin film transistor 10 changes, the thin film transistor 10 has only one turn-on voltage. Thus, the risk of the second active layer 112 and the third active layer 113 forming the “double channel” structure may be reduced, thereby reducing the risk of the threshold voltage of the thin film transistor 10 being negatively biased and reducing the risk of the hump in the characteristic curve of the thin film transistor 10.

For example, as shown in FIG. 14, a difference between a width L4 of the fourth surface 1122 and a width L3 of the third surface 1131 is less than or equal to 0.5 μm. That is, the sum of a distance C between left borders and a distance D between right borders is less than or equal to 0.5 μm.

In some embodiments, a ratio of the etching rate of the second active layer 112 to the etching rate of the third active layer 113 is in a range of 0.2 to 1. The etching of the second active layer 112 is relatively slow, and the etching of the third active layer 113 is relatively fast, so that the second active layer 112 will not be indented relative to the third active layer 113. Thus, the third surface 1131 can be located within the range of the fourth surface 1122, which may reduce the risk of the undercut at the edge of the active layer pattern 11, reduce the risk of the threshold voltage of the thin film transistor 10 being negatively biased and the risk of the hump in the characteristic curve of the thin film transistor 10, and in turn reduce the power consumption of the thin film transistor 10.

In a case where the etching rate of the material of the second active layer 112 is much greater than that of the material of the third active layer 113 (that is, the ratio of the etching rate of the second active layer 112 to the etching rate of the third active layer 113 is greater than 1), the undercut at the edge of the active layer pattern 11 will be generated, thereby causing the threshold voltage of the thin film transistor 10 to be negatively biased.

In a case where the etching rate of the material of the second active layer 112 is much lower than that of the material of the third active layer 113 (that is, the ratio of the etching rate of the second active layer 112 to the etching rate of the third active layer 113 is less than 0.2), a portion of the third active layer 113 close to the substrate 1 is etched relatively fast, and a portion of the third active layer 113 far away from the substrate 1 is etched relatively slow, resulting in the undercut at the edge of the third active layer 113, and causing the threshold voltage of the thin film transistor 10 to be negatively biased. In addition, the etching rate of the third active layer 113 is relatively fast, and the etching rate of the second active layer 112 is relatively slow, which will cause the distance between the border of the third surface 1131 and the border of the fourth surface 1122 to be greater than 0.5 μm. That is, a step is generated at the edge of the second active layer 112 and the third active layer 113. As a result, the second active layer 112 and the third active layer 113 form the “double channel” structure, and the second active layer 112 and the third active layer 113 cannot control the turn-on and turn-off of the thin film transistor 10 as a whole (that is, there are two gate voltages that can make the thin film transistor 10 to be turned on), causing the threshold voltage of the thin film transistor 10 to be negatively biased.

In some embodiments, as shown in FIG. 14, an included angle θ3 between a sidewall of the third active layer 113 and the substrate 1 is approximately in a range of 10° to 90°. For example, the included angle θ3 between the sidewall of the third active layer 113 and the substrate 1 is 10°, 50° or 90°. The embodiments of the present disclosure are not limited thereto. In this way, the risk of the undercut at the edge of the third active layer 113 may be reduced, thereby reducing the risk of the threshold voltage of the thin film transistor 10 being negatively biased.

The included angle θ3 between the sidewall of the third active layer 113 and the substrate 1 is greater than or equal to 10°. For example, the included angle θ3 between the sidewall of the third active layer 113 and the substrate 1 is 15°.

The included angle θ3 between the sidewall of the third active layer 113 and the substrate 1 is less than 90°. For example, the included angle θ3 between the sidewall of the third active layer 113 and the substrate 1 is 85°. Thus, it may be possible to reduce the risk of the included angle θ3 between part of the sidewall of the third active layer 113 and the substrate 1 being greater than 90°, caused by the process error during the formation of the third active layer 113, thereby reducing the risk of the threshold voltage of the thin film transistor 10 being negatively biased, caused by the undercut of part of the sidewall of the third active layer 113.

In some embodiments, as shown in FIG. 14, the included angle θ3 between the sidewall of the third active layer 113 and the substrate 1 is approximately in a range of 30° to 60°. For example, the included angle θ3 between the sidewall of the third active layer 113 and the substrate 1 is 30°, 45°, or 60°, and the embodiments of the present disclosure are not limited thereto. The included angle θ3 between the sidewall of the third active layer 113 and the substrate 1 is greater than or equal to 30°, which may further save the material. The included angle θ3 between the sidewall of the third active layer 113 and the substrate 1 is less than or equal to 60°. Thus, the sidewall of the third active layer 113 is relatively inclined, which may make the interlayer dielectric layer 16 better adhere to the sidewall of the third active layer 113, and reduce the risk of the first active layer 111, the second active layer 112 and the third active layer 113 being short-circuited to the source S and the drain D, caused by breakage of the interlayer dielectric layer 16.

The NBTIS stability of the third active layer 113 is greater than that of the second active layer 112. The NBTIS stability of the third active layer 113 is relatively good, and the concentration of donor defects such as oxygen vacancy defects and hydrogen interstitial defects in the third active layer 113 is relatively low, which may reduce the concentration of donor defects such as oxygen vacancy defects and hydrogen interstitial defects in the active layer pattern 11. As a result, the concentration of carriers in the active layer pattern 11 will not be too high, thereby reducing the risk of the threshold voltage of the thin film transistor 10 being negatively biased, and reducing the power consumption of the thin film transistor 10.

In some embodiments, the material of the third active layer 113 includes indium atoms, and a content of the indium atoms is less than or equal to 40%. For example, the content of the indium atoms is 35%, 15% or 1%. The embodiments of the present disclosure are not limited thereto. The content of the indium atoms in the material of the third active layer 113 is relatively low, the concentration of donor defects such as oxygen vacancy defects and hydrogen interstitial defects in the third active layer 113 is relatively low, and the NBTIS stability of the third active layer 113 is relatively good.

The material of the third active layer 113 includes crystalline oxide, high oxygen type oxide or doped oxide, and the embodiments of the present disclosure are not limited thereto. For example, the material of the third active layer 113 includes crystalline oxide. For example, the material of the third active layer 113 includes indium gallium zinc oxide (IGZO). In dry etching, plasma is difficult to affect the crystalline oxide. The material of the third active layer 113 includes IGZO, which may reduce the risk of the switching characteristic of the thin film transistor 10 being affected. In addition, the crystalline oxide can reduce scattering of carriers, so that the concentration of carriers in the third active layer 113 may be high, which may increase the mobility of carriers in the third active layer 113, and in turn increase the carrier mobility of the active layer pattern 11, increase the carrier mobility of the thin film transistor 10, increase the response speed of the driving thin film transistor 10, and reduce the loss of the thin film transistor 10.

For another example, the material of the third active layer 113 includes the high oxygen type oxide. For example, the material of the third active layer 113 includes IGZO. For example, the mass ratio of the oxygen content in the high oxygen type oxide is approximately in a range of 50% to 80%. For example, the mass ratio of the oxygen content is 50%, 75% or 80%. The embodiments of the present disclosure are not limited thereto.

For yet another example, the material of the third active layer 113 includes the doped oxide, and the doping element in the doped oxide includes Al, Sn, Ga, or a rare earth element. The embodiments of the present disclosure are not limited thereto. For example, the material of the third active layer 113 includes aluminum-doped indium tin zinc oxide (Al-ITZO), praseodymium-doped indium zinc oxide (Pr-IZO) or Pr-IZYO. The embodiments of the present disclosure are not limited thereto. The material of the third active layer 113 may be the same as or different from the material of the first active layer 111.

A conduction band of the third active layer 113 is greater than that of the second active layer 112. In this way, an electron potential barrier is formed between the third active layer 113 and the second active layer 112, which may reduce the risk of carriers in the second active layer 112 diffusing to the third active layer 113, and make most of the carriers located in the second active layer 112. Thus, the mobility of carriers in the second active layer 112 may be increased, and in turn the carrier mobility of the active layer pattern 11 may be increased, the carrier mobility of the thin film transistor 10 may be increased, the response speed of the driving thin film transistor 10 may be increased, and the loss of the thin film transistor 10 may be reduced.

In some embodiments, as shown in FIG. 14, the thickness H3 of the third active layer 113 is in a range of 5 nm to 10 nm. For example, the thickness H3 of the third active layer 113 is 5 nm, 7.5 nm or 10 nm. The embodiments of the present disclosure are not limited thereto. For example, the thickness H3 of the third active layer 113 is 5 nm.

The thickness H3 of the third active layer 113 is less than or equal to 10 nm. Thus, the third active layer 113 is not too thick and does not cause numerous donor defects such as oxygen vacancy defects and hydrogen interstitial defects in the third active layer 113. As a result, it may be possible to reduce the risk of the threshold voltage of the thin film transistor 10 being negatively biased, caused by an excessive concentration of carriers in the active layer pattern 11.

For example, a sum of the thickness H1 of the first active layer 111, the thickness H2 of the second active layer 112, and the thickness H3 of the third active layer 113 is in a range of 30 nm to 50 nm. For example, the sum of the thickness H1 of the first active layer 111, the thickness H2 of the second active layer 112, and the thickness H3 of the third active layer 113 is 30 nm, 40 nm, or 50 nm. The embodiments of the present disclosure are not limited thereto. In the case where the sum of the thickness H1 of the first active layer 111, the thickness H2 of the second active layer 112, and the thickness H3 of the third active layer 113 is greater than or equal to 30 nm, the thicknesses of portions of the active layer pattern 11 may be uniform. Thus, the carrier mobility of each portion of the active layer pattern 11 may be the same, and the uniformity of the carrier mobility of the active layer pattern 11 may be improved. The sum of the thickness H1 of the first active layer 111, the thickness H2 of the second active layer 112, and the thickness H3 of the third active layer 113 is less than or equal to 50 nm, which may reduce the risk of the threshold voltage of the thin film transistor 10 being negatively biased, caused by an excessive concentration of carriers in the active layer pattern 11. Or, the sum of the thickness H1 of the first active layer 111, the thickness H2 of the second active layer 112, and the thickness H3 of the third active layer 113 is less than or equal to 50 nm, which may reduce the risk of the threshold voltage of the thin film transistor 10 being biased, caused by an excessive thickness of the active layer pattern 11, and in turn reduce the risk of poor display of the display apparatus 1000.

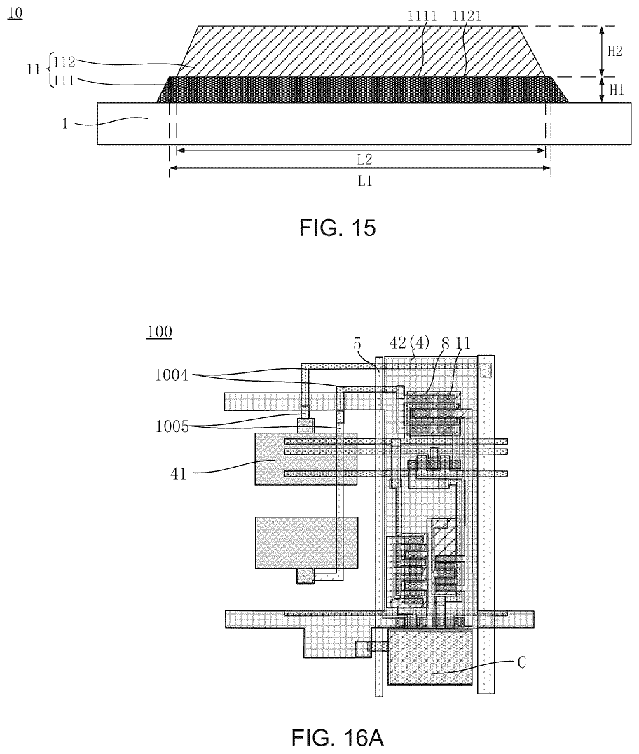

In some embodiments, FIG. 15 is a structural diagram of the first active layer 111 forming a conductive channel. As shown in FIGS. 5 and 15, in the case where the gate G is disposed on the side of the first active layer 111 close to the substrate 1, the carrier mobility of the first active layer 111 is greater than that of the second active layer 112, and carriers in the active layer pattern 11 are gathered to form the conductive channel at a portion of the first active layer 111 close to the gate G. Thus, carriers may flow from the source S to the drain D to achieve the turn-on of the thin film transistor 10.

For example, the carrier mobility of the first active layer 111 is greater than or equal to 20 cm2/V·s, and the material of the first active layer 111 includes indium zinc oxide (IZO), indium gallium oxide (IGO), indium gallium tin oxide (IGTO) or indium tin zinc oxide (ITZO). The embodiments of the present disclosure are not limited thereto. For example, the material of the first active layer 111 includes IGTO.

The NBTIS stability of the first active layer 111 is less than that of the second active layer 112. There are relatively few donor defects such as oxygen vacancy defects and hydrogen interstitial defects in the second active layer 112, which can reduce the concentration of the donor defects such as oxygen vacancy defects and hydrogen interstitial defects in the active layer pattern 11. The carrier concentration of the active layer pattern 11 is not too high, which may reduce the risk of the threshold voltage of the thin film transistor 10 being negatively biased, and reduce the power consumption of the thin film transistor 10.

The material of the second active layer 112 includes indium atoms, and a content of the indium atoms is less than or equal to 40%. For example, the content of the indium atoms is 35%, 15% or 1%. The embodiments of the present disclosure are not limited thereto. The content of the indium atoms in the material of the second active layer 112 is relatively low, there are few donor defects such as oxygen vacancy defects and hydrogen interstitial defects in the second active layer 112, and the NBTIS stability of the second active layer 112 is relatively good.

The material of the second active layer 112 includes crystalline oxide, high oxygen type oxide or doped oxide, and the embodiments of the present disclosure are not limited thereto.

For example, the material of the second active layer 112 includes crystalline oxide. For example, the material of the second active layer 112 includes IGZO. In dry etching, plasma is difficult to affect the crystalline oxide. The material of the second active layer 112 includes IGZO, which may reduce the risk of the characteristic of the thin film transistor 10 being affected. In addition, the crystalline oxide can reduce scattering of carriers, so that the concentration of carriers in the second active layer 112 may be high, which may increase the carrier mobility of the second active layer 112, and in turn increase the carrier mobility of the active layer pattern 11, increase the carrier mobility of the thin film transistor 10, increase the response speed of the driving thin film transistor 10, and reduce the loss of the thin film transistor 10.

For another example, the material of the second active layer 112 includes the high oxygen type oxide. For example, the material of the second active layer 112 includes IGZO. For example, the mass ratio of the oxygen content in the high oxygen type oxide is approximately in a range of 50% to 80%. For example, the mass ratio of the oxygen content is 50%, 75% or 80%. The embodiments of the present disclosure are not limited thereto.

For yet another example, the material of the second active layer 112 includes the doped oxide, and the doping element in the doped oxide includes Al, Sn, Ga, or a rare earth element. The embodiments of the present disclosure are not limited thereto. For example, the material of the second active layer 112 includes aluminum-doped indium tin zinc oxide (Al-ITZO), praseodymium-doped indium zinc oxide (Pr-IZO) or Pr-IZYO. The embodiments of the present disclosure are not limited thereto.

The second active layer 112 is further away from the gate G than the first active layer 111. That is, the first active layer 111 is located between the second active layer 112 and the gate G. The light directed to the first active layer 111 from the substrate 1 will be blocked by the gate G, so that the light cannot reach the first active layer 111, and the energy band of the first active layer 111 is not bent, which reduce the risk of the carriers in the first active layer 111 drifting toward the gate insulating layer 15 and being captured by oxygen vacancies and hydrogen interstitials in the gate insulation layer 15, and in turn reduce the risk of the threshold voltage of the thin film transistor 10 being negatively biased, caused by carrier accumulation at the interface of the gate insulating layer 15. Light in a direction from a side, away from the first active layer 111, of the second active layer 112 to the first active layer 111 will be blocked by the second active layer 112. The light is incident on the second active layer 112, and there are few donor defects such as oxygen vacancy defects and hydrogen interstitial defects in the second active layer 112. Thus, the carrier concentration of the active layer pattern 11 is not too high, which may reduce the risk of the threshold voltage of the thin film transistor 10 being negatively biased.

A conduction band of the second active layer 112 is greater than that of the first active layer 111. In this way, an electron potential barrier is formed between the second active layer 112 and the first active layer 111, which may reduce the risk of carriers in the first active layer 111 diffusing to the second active layer 112, and make most of the carriers located in the first active layer 111. Thus, the mobility of carriers in the first active layer 111 may be increased, and in turn the carrier mobility of the active layer pattern 11 may be increased, the carrier mobility of the thin film transistor 10 may be increased, the response speed of the driving thin film transistor 10 may be increased, and the loss of the thin film transistor 10 may be reduced.

In some embodiments, as shown in FIG. 15, the ratio of the thickness H2 of the second active layer 112 to the thickness H1 of the first active layer 111 is in a range of 2 to 5. For example, the ratio of the thickness H2 of the second active layer 112 to the thickness H1 of the first active layer 111 is 2, 3.5 or 5. The embodiments of the present disclosure are not limited thereto.

The ratio of the thickness H2 of the second active layer 112 to the thickness H1 of the first active layer 111 is greater than or equal to 2. In this way, the first active layer 111 is relatively thin, which will not cause the concentration of carriers in the active layer pattern 11 to be too high, will not cause the threshold voltage of the thin film transistor 10 to be negatively biased, will not cause a large leakage current of the thin film transistor 10, and will not cause abnormal display of the display apparatus 1000.

The ratio of the thickness H2 of the second active layer 112 to the thickness H1 of the first active layer 111 is less than or equal to 5. In this way, the second active layer 112 is not too thick, which may reduce the risk of the threshold voltage of the thin film transistor 10 being biased, caused by an excessive thickness of the active layer pattern 11, and in turn reduce the risk of poor display of the display apparatus 1000.

In some embodiments, as shown in FIG. 15, the thickness of the first active layer 111 is greater than or equal to 5 nm. The first active layer 111 is not too thin, which will not cause the concentration of carriers in the first active layer 111 to be low, and will not cause a low carrier mobility of the first active layer 111. Moreover, during the process of manufacturing the first active layer 111, the thicknesses of portions of the first active layer 111 are uniform, so that the carrier mobility of each portion of the first active layer 111 is the same. Thus, the uniformity of the carrier mobility of the first active layer 111 may be improved. In addition, it may also be possible to reduce the risk of low carrier mobility of the first active layer 111 caused by a thin portion of the first active layer 111 being unable to pass carriers.

In some embodiments, as shown in FIG. 15, the thickness H2 of the second active layer 112 is greater than or equal to 20 nm. The second active layer 112 is relatively thick, which will not cause the concentration of carriers in the active layer pattern 11 to be too high, will not cause the threshold voltage of the thin film transistor 10 to be negatively biased, and will not cause a large leakage current of the thin film transistor 10, and will not cause abnormal display of the display apparatus 1000.

In some embodiments, as shown in FIG. 8, during a process of forming a source-drain conductive layer, a portion of the second active layer 112 is removed by the etching solution. Therefore, the sum of the thickness of the first active layer 111 and the thickness of the second active layer 112 is in a range of 50 nm to 100 nm. For example, the sum of the thickness H1 of the first active layer 111 and the thickness H2 of the second active layer 112 is 50 nm, 75 nm, or 100 nm. The embodiments of the present disclosure are not limited thereto. In the case where the sum of the thickness H1 of the first active layer 111 and the thickness H2 of the second active layer 112 is greater than or equal to 50 nm, during the process of manufacturing the active layer pattern 11, the thickness of the active layer pattern 11 is uniform, which may make the carrier mobility of each portion of the active layer pattern 11 the same, and may improve the uniformity of the carrier mobility of the active layer pattern 11. The sum of the thickness of the first active layer 111 and the thickness of the second active layer 112 is less than or equal to 100 nm, which may reduce the risk of the threshold voltage of the thin film transistor 10 being negatively biased, caused by an excessive thickness of the first active layer 111 (the excessive thickness of the first active layer 111 will cause an excessive carrier concentration of the active layer pattern 11). Or, the sum of the thickness of the first active layer 111 and the thickness of the second active layer 112 is less than or equal to 100 nm, which may reduce the risk of the threshold voltage of the thin film transistor 10 being biased, caused by an excessive thickness of the second active layer 112 (the excessive thickness of the second active layer 112 will cause the thickness of the active layer pattern 11 to be relatively large), and in turn reduce the risk of poor display of the display apparatus 1000.

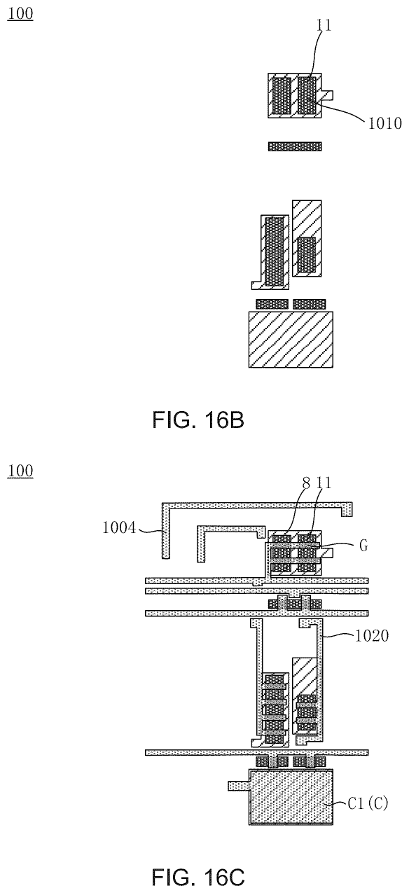

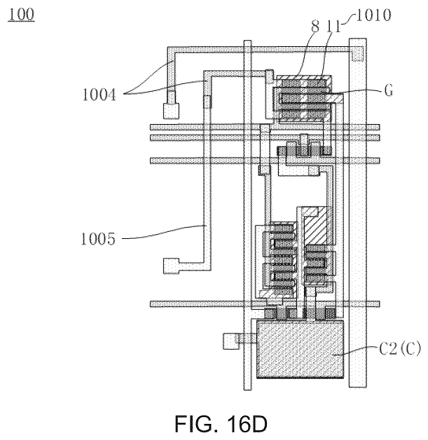

FIG. 16A is a structure diagram showing a light-shielding layer and a conductive layer that are stacked. In some embodiments, as shown in FIGS. 4 and 16A, the array substrate 1100 further includes the conductive layer 4 located between the driving circuit 2 and the light-emitting chip 3. The conductive layer 4 is connected to the driving circuit 2. The conductive layer 4 includes pads 41. A pad 41 is configured to be connected to the light-emitting chip 3. In this way, the light-emitting chip 3 is connected to the array substrate 1100, and the driving circuit 2 may drive the light-emitting chip 3 to emit light, so that the display apparatus 1000 emits light.

For example, a material of the conductive layer 4 includes metal. For example, the material of the conductive layer 4 may include silver, aluminum, or copper. The embodiments of the present disclosure are not limited thereto. For example, the material of the conductive layer 4 includes copper. A thickness of the conductive layer 4 is in a range of 60 nm to 200 nm. For example, the thickness of the conductive layer 4 is 60 nm, 120 nm or 200 nm. The embodiments of the present disclosure are not limited thereto.

In some embodiments, as shown in FIGS. 4 and 16A, the array substrate 1100 further includes a source-drain conductive layer 5, and the source S and the drain D are located in the source-drain conductive layer 5. The first active layer 111 and the second active layer 112 of the thin film transistor 10 are closer to the substrate 1 than the source-drain conductive layer 5. The source S and the drain D are in contact with the second active layer 112. A material of the source-drain conductive layer 5 may include molybdenum, aluminum, copper or other conductive materials. A thickness of the source-drain conductive layer 5 is in a range of 50 nm to 150 nm. For example, the thickness of the source-drain conductive layer 5 is 50 nm, 100 nm or 150 nm. The embodiments of the present disclosure are not limited thereto.

In some embodiments, as shown in FIG. 4, the array substrate 1100 has an array region 101 and a bonding region 102, and the bonding region 102 is located on a side of the array region 101. The plurality of thin film transistors 10 are located in the array region 101. The source-drain conductive layer 5 further includes pins 51 located in the bonding region 102, and the pins 51 are configured to be connected to a circuit board. The circuit board may be a chip on film (COF) circuit board, a chip on glass (COG) circuit board, a flexible printed circuit (FPC) or driver chip, and the embodiments of the present disclosure are not specifically limited thereto. For example, the circuit board is the FPC.

In the related art, materials of pads and pins are both copper. In a process of bonding the light-emitting chip to the pads, the pins are exposed to the air. The copper of the pins is easily oxidized, and copper oxide is formed after copper is oxidized. Copper oxide has poor conductivity, resulting in poor conductivity of the pins.

In order to solve the above problem, in some embodiments of the present disclosure, the reducibility of the material of the source-drain conductive layer 5 in the array substrate 1100 is lower than that of the conductive layer 4. In this way, the material of the source-drain conductive layer 5 is not reactive (that is, the material of the pins 51 is not reactive), which may reduce the risk of the pins 51 being oxidized.

For example, the material of the source-drain conductive layer 5 includes molybdenum, and the material of the conductive layer 4 includes copper or aluminum. Molybdenum has poor reducibility, which reduces the risk of the pins 51 being oxidized. The pin 51 is of a single-layer structure or a multi-layer structure. In the case where the pin 51 is of the multi-layer structure, a material of a layer of the pin 51 that is farthest away from the substrate 1 is molybdenum. In this way, it may be possible to reduce the risk of the pin 51 being oxidized. For example, the pin 51 includes copper and molybdenum that are stacked; or, the pin 51 includes aluminum and molybdenum that are stacked; or, the pin 51 includes copper, aluminum and molybdenum that are stacked. The embodiments of the present disclosure are not limited thereto.

In some embodiments, as shown in FIG. 4, the array substrate 1100 further includes a second passivation layer 6. The second passivation layer 6 is located between the source-drain conductive layer 5 and the conductive layer 4. The second passivation layer 6 may reduce the risk of moisture and impurities in the air entering the source-drain conductive layer 5, thereby reducing the risk of the source-drain conductive layer 5 being damaged and extending the service life of the array substrate 1100. The second passivation layer 6 may also isolate the source S and the drain D, thereby reducing the risk of short circuit between the source S and the drain D.

A material of the second passivation layer 6 includes an insulating material. For example, the material of the second passivation layer 6 includes silicon oxide, silicon nitride, silicon oxynitride, aluminum oxide or titanium oxide. The embodiments of the present disclosure are not limited thereto. For example, the material of the second passivation layer 6 includes silicon nitride. A thickness of the second passivation layer 6 is in a range of 200 nm to 400 nm. For example, the thickness of the second passivation layer 6 is 200 nm, 300 nm, or 400 nm. The embodiments of the present disclosure are not limited thereto.

In some embodiments, as shown in FIG. 4, the array substrate 1100 further includes an insulating protective layer 7. The insulating protective layer 7 is located on a side of the conductive layer 4 away from the substrate 1. The insulating protective layer 7 is provided therein with avoidance holes located in the array region 101. An orthographic projection of an avoidance hole on the substrate 1 at least partially overlaps with an orthographic projection of the pad 41 on the substrate 1. In this way, the insulating protective layer 7 may be used to reduce the risk of part of the conductive layer 4 being oxidized. In addition, a portion of the pad 41 exposed by the avoidance hole is configured to be connected to the light-emitting chip 3. In this way, the light-emitting chip 3 may be connected to the array substrate 1100.

At least part of an orthographic projection of the pin 51 on the substrate 1 is located outside an orthographic projection of the insulating protective layer 7 on the substrate 1, and the portion of the pin 51 exposed by the insulating protective layer 7 is configured to be connected to the circuit board. That is, the circuit board is bonded to the array substrate 1100.

A material of the insulating protective layer 7 includes silicon oxide, silicon nitride, silicon oxynitride, aluminum oxide or titanium oxide, and the embodiments of the present disclosure are not limited thereto. A thickness of the insulating protective layer 7 is in a range of 10 nm to 20 nm. For example, the thickness of the insulating protective layer 7 is 10 nm, 15 nm or 20 nm. The embodiments of the present disclosure are not limited thereto.

In some embodiments, as shown in FIGS. 4 and 16A (in order to illustrate the conductive layer 4 and the light-shielding layer 8, the insulating protective layer 7 is omitted in FIG. 16A), at least one thin film transistor 10 is a driving transistor. An orthographic projection of the conductive layer 4 on the substrate 1 covers an orthographic projection of the first active layer 111 included in the driving transistor on the substrate 1. Light in a direction from a side, away from the driving transistor, of the conductive layer 4 to the driving transistor is blocked by the conductive layer 4, so that the light cannot reach the active layer pattern 11, which may reduce the risk of the threshold voltage of the driving transistor being negatively biased.

In some embodiments, as shown in FIG. 16A, the conductive layer 4 further includes metal lines 42, an orthographic projection of a metal line 42 on the substrate 1 covers that of the first active layer 111 included in the driving transistor on the substrate 1.

For example, the metal lines 42 include VDD lines and VSS lines. Due to a large current of the driving circuit, the current density on the VDD line and VSS line 42 is very large, and the VDD line and VSS line are made relatively wide or thick. Thus, the VDD line and VSS line may be used to block light. That is, the orthographic projection of the VDD line and VSS line on the substrate 1 covers the orthographic projection of the first active layer 111 included in the driving transistor on the substrate 1.

In some embodiments, as shown in FIGS. 4 and 16A, the array substrate 1100 further includes a light-shielding layer 8 located between the thin film transistor 10 and the substrate 1, and an orthographic projection of the light-shielding layer 8 on the substrate 1 covers that of the first active layer 111 on the substrate 1. Light in a direction from a side, away from the driving transistor, of the light-shielding layer 8 to the driving transistor is blocked by the light-shielding layer 8, so that the light cannot reach the active layer pattern 11, which may reduce the risk of the threshold voltage of the driving transistor being negatively biased.

The light-shielding layer 8 is connected to the source S or the drain D, which may make the current on the source-drain conductive layer 5 more stable, thereby improving the electrical performance of the driving transistor.

In some embodiments, as shown in FIG. 4, the array substrate 1100 further includes a planarization layer 9 and a first passivation layer 110. The planarization layer 9 is located between the source-drain conductive layer 5 and the conductive layer 4. A material of the planarization layer 9 may include resin. The first passivation layer 110 is located between the planarization layer 9 and the conductive layer 4, and is in contact with the planarization layer 9 and the conductive layer 4. A material of the first passivation layer 110 includes silicon oxide, silicon nitride, silicon oxynitride, aluminum oxide or titanium oxide. For example, the material of the first passivation layer 110 is silicon oxide. Different materials of the first passivation layer 110 and the planarization layer 9 can make the adhesion force between the first passivation layer 110 and the conductive layer 4 greater than the adhesion force between the conductive layer 4 and the planarization layer 9, which may reduce the risk of the conductive layer 4 falling off from the array substrate 1100.

There will be some moisture in the planarization layer 9. After the planarization layer 9 is manufactured, in order to release the moisture in the planarization layer 9, the first passivation layer 110 is provided therein with a plurality of first vent holes 1110. Part of the planarization layer 9 is exposed by the first vent holes 1110, so that the moisture in the planarization layer 9 may be released through the first vent holes 1110, and the risk of bulging of the planarization layer 9 may be reduced.

In the case where the array substrate 1100 includes the insulating protective layer 7, the insulating protective layer 7 is provided therein with a plurality of second vent holes 71 connected to respective first vent holes 1110. In this way, the moisture in the planarization layer 9 may be released through the first vent holes 1110 and second vent holes 71, and the risk of bulging of the planarization layer 9 may be reduced.

FIG. 16B is a structural diagram showing the light-shielding layer and a semiconductor layer that are stacked, and FIG. 16C is a structural diagram showing the light-shielding layer, the semiconductor layer and a gate conductive layer that are stacked. In some embodiments, as shown in FIGS. 4, 16B and 16C, the array substrate 1100 further includes the semiconductor layer 1010 and the gate conductive layer 1020. As shown in FIG. 16B, the semiconductor layer 1010 is disposed on the substrate 1, and the active layer pattern 11 is located in the semiconductor layer 1010.

As shown in FIGS. 4 and 16C, the gate conductive layer 1020 is disposed on the substrate 1, and the gate G of the thin film transistor 10 is located in the gate conductive layer 1020. The gate conductive layer 1020 further includes a first plate C1 of the storage capacitor C, gate patterns 1003 and first connection lines 1004. The first plate C1 is located below the gate. The gate pattern 1003 is located in the bonding region 102 and connected to the pin 51. In this way, the circuit board may control the turn-on or turn-off of the thin film transistor 10. FIG. 16D is a structural diagram showing the light-shielding layer, the semiconductor layer, the gate conductive layer and the source-drain conductive layer that are stacked. As shown in FIG. 16D, an end of a first connection line 1004 is connected to the source or drain in the source-drain conductive layer 4.

As shown in FIGS. 4 and 16D, the source-drain conductive layer 5 further includes a second plate C2 of the storage capacitor C and second connection lines 1005. An end of a second connection line 1005 is connected to another end of the first connection line 1004. As shown in FIG. 16A, another end of the second connection line 1005 is connected to the pad 41.

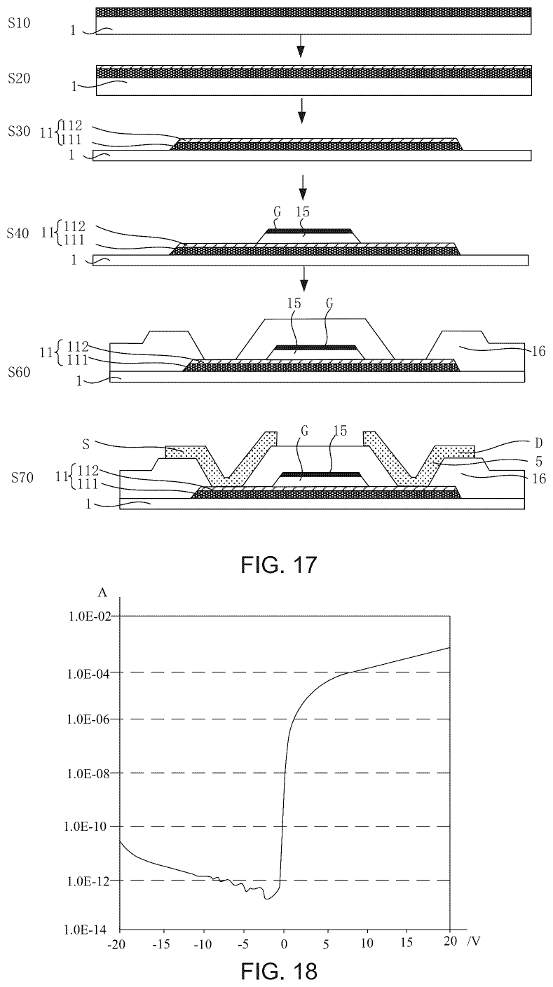

Embodiments of the present disclosure further provide a method for manufacturing the thin film transistor 10. For example, the gate G is disposed on the side of the second active layer 112 away from the substrate 1, and as shown in FIG. 17, the manufacturing method includes S10 to S70.

In S10, a first semiconductor material is deposited on the substrate 1 to form a first initial active layer.

For example, the first semiconductor material may be deposited using a thin film deposition process such as chemical vapor deposition (CVD), physical vapor deposition (PVD), atomic layer deposition (ALD) or any combination thereof. For the first semiconductor material, reference is made to the material of the first active layer 111. For example, the first semiconductor material is IZYO. A thickness of the deposited first semiconductor material may be greater than or equal to 20 nm, for example, may be 20 nm. The first initial active layer may be of an entire layer structure covering the substrate 1.

In S20, a second semiconductor material is deposited on the first initial active layer to form a second initial active layer.

For example, the second semiconductor material may be deposited using a thin film deposition process such as CVD, PVD, ALD or any combination thereof. For the second semiconductor material, reference is made to the material of the second active layer 112. For example, the second semiconductor material is IGTO. A thickness of the deposited second semiconductor material may be greater than or equal to 5 nm, for example, may be 10 nm. The second initial active layer may be of an entire layer structure covering the first initial active layer.

In S30, the first initial active layer and the second initial active layer are patterned to form the first active layer 111 and the second active layer 112, respectively.

For example, the first active layer 111 and the second active layer 112 may be formed using a dry or wet etching process. The first active layer 111 and the second active layer 112 are formed at the same time without adding additional processes. The first active layer 111 includes the first surface 1111 away from the substrate 1, and the second active layer 112 includes the second surface 1121 in contact with the first surface 1111. The first surface 1111 coincides with the second surface 1121. The included angle θ1 between the sidewall of the first active layer 111 and the substrate 1 is 41°, and the included angle θ2 between the sidewall of the second active layer 112 and the substrate 1 is 41°.

In S40, the gate insulating layer 15 and the gate G are formed on the side of the second active layer 112 away from the substrate 1.

A material of the gate insulating layer 15 may include silicon oxide, silicon nitride, silicon oxynitride, aluminum oxide or titanium oxide, and the embodiments of the present disclosure are not limited thereto. For example, the material of the gate insulating layer 15 includes silicon nitride. A thickness of the gate insulating layer 15 is in a range of 100 nm to 200 nm, inclusive.

A material of the gate G may include silver, aluminum, chromium or copper, and the embodiments of the present disclosure are not limited thereto. For example, the material of the gate G includes copper. A thickness of the gate G is in a range of 50 nm to 150 nm, inclusive.

In S50, a doping process is performed on the first active layer 111 and the second active layer 112 to make the first active layer 111 and the second active layer 112 conductive by using the gate G as a mask.

In S60, the interlayer dielectric layer 16 is formed on the side of the gate G away from the substrate 1.

A material of the interlayer dielectric layer 16 includes silicon oxide, silicon nitride, silicon oxynitride, aluminum oxide or titanium oxide, and the embodiments of the present disclosure are not limited thereto. For example, the material of the interlayer dielectric layer 16 includes silicon oxide. A thickness of the interlayer dielectric layer 16 is in a range of 200 nm to 500 nm, inclusive.

In S70, the source-drain conductive layer 5 is formed on the side of the interlayer dielectric layer 16 away from the substrate 1.

A material of the source-drain conductive layer 5 may include molybdenum, aluminum, copper or other conductive materials. A thickness of the source-drain conductive layer 5 is in a range of 50 nm to 150 nm, inclusive. The source S and the drain D in the source-drain conductive layer 5 are in contact with the second active layer 112 through via holes.

It should be understood that, the current value of the TFT is 1.0E-08, and the corresponding voltage value is approximately 0, which may be considered that the threshold voltage of the thin film transistor 10 is not negatively biased or positively biased. The characteristic curve obtained through experiments on the thin film transistor 10 manufactured by the above method is shown in FIG. 18. The horizontal axis in FIG. 18 is the voltage value of the TFT, and the vertical axis in FIG. 18 is the current value of the TFT. The voltage value corresponding to the current value of 1.0E-08 is approximately 0. That is, the threshold voltage of the thin film transistor 10 is not negatively biased or positively biased.

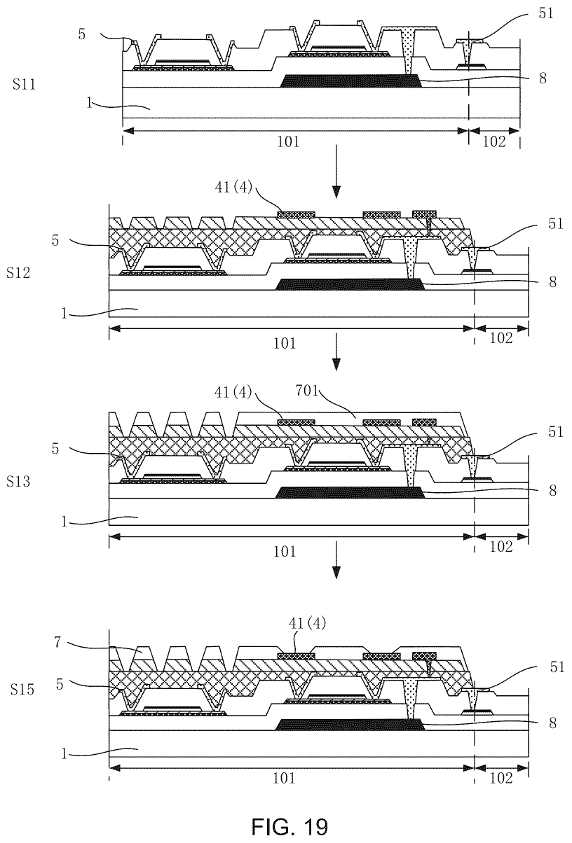

Embodiments of the present disclosure further provide a method for manufacturing an array substrate 1100. The array substrate 1100 has an array region 101 and a bonding region 102. As shown in FIG. 19, the manufacturing method includes S11 to S15.

In S11, the source-drain conductive layer 5 is formed on the substrate 1.

The source-drain conductive layer 5 includes pins 51 located in the bonding region 102, and the pins 51 are configured to be connected to a circuit board. A material of the source-drain conductive layer 5 may include molybdenum, aluminum, copper or other conductive materials. A thickness of the source-drain conductive layer 5 is in a range of 50 nm to 150 nm, inclusive.

In S12, the conductive layer 4 is formed on the side of the source-drain conductive layer 5 away from the substrate 1.

The conductive layer 4 includes pads 41 located in the array region 101. A Pad 41 is configured to be connected to the light-emitting chip 3. For example, a material of the conductive layer 4 includes metal. The material of the conductive layer 4 may include silver, aluminum, or copper, and the embodiments of the present disclosure are not limited thereto. For example, the material of the conductive layer 4 includes copper. A thickness of the conductive layer 4 is in a range of 60 nm to 200 nm, inclusive.

In S13, an initial insulating protective layer 701 is formed on the side of the conductive layer 4 away from the substrate 1.

An orthographic projection of the initial insulating protective layer 701 on the substrate 1 covers that of the conductive layer 4 on the substrate 1. A material of the initial insulating protective layer 701 includes silicon oxide, silicon nitride, silicon oxynitride, aluminum oxide or titanium oxide, and the embodiments of the present disclosure are not limited thereto. A thickness of the initial insulating protective layer 701 is in a range of 10 nm to 20 nm, inclusive.

In S14, an annealing treatment is performed on the array substrate 1100.

During the annealing treatment of the array substrate 1100, the conductive layer 4 is covered by the initial insulating protective layer 701, and the pads 41 in the conductive layer 4 are not easily oxidized, which may reduce the risk of the conductivity of the pad 41 being decreased.

In S15, portions of the initial insulating protective layer 701 are removed to form a plurality of avoidance holes, so as to form the insulating protective layer 7.

An orthographic projection of an avoidance hole on the substrate 1 at least partially overlaps with an orthographic projection of the pad 41 on the substrate 1, and a portion of the pad 41 exposed by the avoidance hole is configured to be connected to the light-emitting chip 3. In this way, the process of connecting the light-emitting chip 3 to the pad 41 is not affected.

In the description of the specification, the specific features, structures, materials or characteristics may be combined in any one or more embodiments or examples in a suitable manner.

The above are only specific embodiments of the present disclosure, but the scope of protection of the present disclosure is not limited, and any person skilled in the art may conceive of variations or replacements within the technical scope of the present disclosure, which shall be included in the protection scope of the present disclosure. Therefore, the protection scope of the present disclosure should be determined by the protection scope of the claims.

What is claimed is:

1. A thin film transistor, comprising:
a first active layer disposed on a side of a substrate, the first active layer including a first surface away from the substrate;
a second active layer disposed on a side of the first active layer away from the substrate, the second active layer including a second surface in contact with the first surface;
a first electrode, wherein the first electrode, the first active layer and the second active layer have an overlapping region among orthographic projections of the first electrode, the first active layer and the second active layer on the substrate;
a second electrode, wherein the second electrode, the first active layer and the second active layer have an overlapping region among orthographic projections of the second electrode, the first active layer and the second active layer on the substrate; and
a third electrode, wherein the third electrode, the first active layer and the second active layer have an overlapping region among orthographic projections of the third electrode, the first active layer and the second active layer on the substrate, and the third electrode is opposite to the second electrode;
wherein the second surface is located within the first surface, and a distance between at least part of a border of the second surface and a border of the first surface is less than or equal to 0.5 μm.

2. The thin film transistor according to claim 1, wherein an orthographic projection, on the substrate, of a surface of the first active layer close to the second active layer covers an orthographic projection, on the substrate, of a surface of the second active layer close to the first active layer.

3. The thin film transistor according to claim 1, wherein the second surface includes a first region, and an orthographic projection of the first region on the substrate completely overlaps with an orthographic projection of the first electrode on the substrate; a distance between a border of the first region and the border of the first surface is less than or equal to 0.5 μm.

4. The thin film transistor according to claim 1, wherein
an included angle between a sidewall of the first active layer and the substrate is in a range of 10° to 90°; and/or,
an included angle between a sidewall of the second active layer and the substrate is in a range of 10° to 90°.

5. The thin film transistor according to claim 1, wherein the first electrode is disposed on a side of the second active layer away from the substrate;
a carrier mobility of the first active layer is less than that of the second active layer, and a conduction band of the first active layer is greater than that of the second active layer.

6. The thin film transistor according to claim 5, wherein a ratio of a thickness of the first active layer to a thickness of the second active layer is in a range of 2 to 5.

7. The thin film transistor according to claim 6, wherein
the thickness of the second active layer is greater than or equal to 5 nm; and/or
the thickness of the first active layer is greater than or equal to 20 nm; and/or
a sum of the thickness of the first active layer and the thickness of the second active layer is in a range of 30 nm to 50 nm.

8. The thin film transistor according to claim 5, further comprising:
a third active layer disposed on a side of the second active layer away from the substrate, the third active layer including a third surface in contact with the second active layer, wherein
the second active layer further includes a fourth surface in contact with the third surface, the third surface is located within the fourth surface, and a distance between a border of the third surface and a border of the fourth surface is less than or equal to 0.5 μm.

9. The thin film transistor according to claim 8, wherein an included angle between a sidewall of the third active layer and the substrate is in a range of 10° to 90°; and/or
a thickness of the third active layer is in a range of 5 nm to 10 nm; and/or
a sum of a thickness of the first active layer, a thickness of the second active layer, and a thickness of the third active layer is in a range of 30 nm to 50 nm.

10. The thin film transistor according to claim 8, wherein
a material of the first active layer includes indium gallium zinc oxide, praseodymium-doped indium zinc oxide, or aluminum-doped indium tin zinc oxide; and/or
a material of the second active layer includes indium zinc oxide, indium gallium oxide, indium gallium tin oxide or indium tin zinc oxide; and/or
a material of the third active layer includes indium gallium zinc oxide, praseodymium-doped indium zinc oxide, or aluminum-doped indium tin zinc oxide.

11. The thin film transistor according to claim 1, wherein the first electrode is disposed on a side of the first active layer close to the substrate;
a carrier mobility of the first active layer is greater than that of the second active layer, and a conduction band of the first active layer is less than that of the second active layer.

12. The thin film transistor according to claim 11, wherein a ratio of a thickness of the second active layer to a thickness of the first active layer is in a range of 2 to 5.

13. The thin film transistor according to claim 12, wherein
the thickness of the first active layer is greater than or equal to 5 nm; and/or
the thickness of the second active layer is greater than or equal to 20 nm; and/or
a sum of the thickness of the first active layer and the thickness of the second active layer is in a range of 50 nm to 100 nm.

14. The thin film transistor according to claim 11, wherein
a material of the first active layer includes indium zinc oxide, indium gallium oxide, indium gallium tin oxide or indium tin zinc oxide; and/or
a material of the second active layer includes indium gallium zinc oxide, praseodymium-doped indium zinc oxide, or aluminum-doped indium tin zinc oxide.

15. An array substrate, comprising:
a substrate;
a plurality of thin film transistors each according to claim 1, the plurality of thin film transistors being disposed on a side of the substrate.

16. The array substrate according to claim 15, further comprising:
a conductive layer disposed on a side of the plurality of thin film transistors away from the substrate and connected to the plurality of thin film transistors; and
a light-emitting chip disposed on the side of the plurality of thin film transistors away from the substrate, wherein the conductive layer includes pads, and a pad is connected to the light-emitting chip, wherein
the array substrate has an array region and a bonding region; the array substrate further comprises a driving circuit, and the plurality of thin film transistors are located in the driving circuit;
the driving circuit includes a source-drain conductive layer including pins located in the bonding region, the pins being configured to be connected to a circuit board, wherein
a reducibility of a material of the source-drain conductive layer is lower than that of a material of the conductive layer.

17. The array substrate according to claim 16, further comprising:
an insulating protective layer located on a side of the conductive layer away from the substrate, wherein the insulating protective layer is provided therein with avoidance holes located in the array region, and an orthographic projection of an avoidance hole on the substrate at least partially overlaps with an orthographic projection of the pad on the substrate; a portion of the pad exposed by the avoidance hole is configured to be connected to the light-emitting chip.

18. The array substrate according to claim 16, wherein at least one thin film transistor is a driving transistor; and an orthographic projection of the conductive layer on the substrate covers an orthographic projection of a first active layer included in the driving transistor on the substrate; and
the array substrate further comprises:
a light-shielding layer located between the driving transistor and the substrate, wherein an orthographic projection of the light-shielding layer on the substrate covers that of the first active layer on the substrate.

19. The array substrate according to claim 16, further comprising:
a planarization layer located between the plurality of thin film transistors in the driving circuit and the conductive layer; and
a first passivation layer located between the planarization layer and the conductive layer and being in contact with the planarization layer and the conductive layer, wherein an adhesion force between the first passivation layer and the conductive layer is greater than an adhesion force between the conductive layer and the planarization layer.

20. A display apparatus, comprising:
the array substrate according to claim 15.
